(19) United States
(12) Patent Application Publication
(10) Pub. No.: US 2024/0301554 A1
(43) Pub. Date: Sep. 12, 2024

(54) GRAPHENE COATED NON-METALLIC SURFACES, DEVICES AND METHOD THEREOF

(71) Applicants: 2D GENERATION LTD., YEHUD-MONOSSON (IL); BAR-ILAN UNIVERSITY, RAMAT GAN (IL)

(72) Inventor: Doron Yaacov NAVEH, Petach Tivka (IL)

(21) Appl. No.: 18/574,061

(22) PCT Filed: Jun. 29, 2022
(86) PCT No.: PCT/IL2022/050701

§ 371 Date: Dec. 25, 2023

Related U.S. Application Data
(60) Provisional application No. 63/216,004, filed on Jun. 29, 2021.
(60) Provisional application No. 63/245,956, filed on Sep. 20, 2021.
(60) Provisional application No. 63/310,307, filed on Feb. 15, 2022.

(51) Int. Cl. C23C 16/455; C23C 16/26; C23C 16/48

(52) U.S. Cl. CPC C23C 16/45553; C23C 16/26; C23C 16/482; C23C 16/483

(57) ABSTRACT

A method for coating a non-metallic surface (NMS) by a graphene layer by depositing a graphene molecular precursor comprising a compound having an aromatic hydrocarbon component that is derivatized by a tethering group. The tethering groups react with the NMS to form a covalent bond between the compound of the graphene molecular precursor and the non-metallic surface, and the graphene molecular precursor is transformed into a graphene interfacial layer which is covalently bound to the non-metallic surface. Alternatively, hydrophobic molecules are deposited on top of the non-metallic surface to which they covalently link, followed by self-assembly of molecular graphene precursor to the hydrophobic molecules and transformed into a graphene layer.

### TECHNICAL FIELD

The present invention relates to semiconductor devices. In particular, the invention relates to coating of dielectric surfaces by carbon allotropes, in particular graphene and devices containing them.

### BACKGROUND ART

The systematic miniaturization of integrated circuits elements was and is the main driving force of very large system integration (VLSI) over the past five decades. Smaller transistors were translated to higher density of circuit elements per area and to faster clock rates. On the other hand, as result of scaling down interconnection metal lines have lower conductivity, or increased energy consumption. For example, in modern computer processor the energy losses on interconnections amounts to about 60% of the total dynamic power consumption of the processor [3]. Yet, interconnections are aggressively scaled at every technology generation and are the pillars sustaining the increased circuit density. Moreover, in concurrent technology generations (2020), signal transmission delay of 1 mm-long global interconnect is expected to be larger by factor of 40 times than the transistor gate intrinsic delay time.

Consider copper interconnects as an illustrative example. In general, electron propagation in metallic media is well described by models of (nearly) free electron gas, describing the conductivity as proportion of the time passing between two scattering events where electrons are free to propagate without disturbance, and passing a distance termed mean free path. Specifically, the mean free path of copper at room temperature is about 40 nm and is already comparable to the pitch size of interconnections of 22 nm technology. When current carrying wire is scaled to its mean free path, the effects of electron scattering from the wire boundaries become increasingly more significant and the resistivity shoots up rapidly. Additional issues with smaller dimension metal interconnects also evident with copper interconnects. Copper is a highly diffusive material that easily penetrates silicon and dielectrics which are used to separate the different layers of circuit elements (e.g., transistors) and interconnects. This diffusion of metal atoms may cause degradation, resulting, inter alia, in leakage and short paths across dielectrics, formation of deep level traps that enhance leakage currents at p-n junctions, and degradation of minority carrier lifetime that limit the effectiveness of electronic device.

Therefore, it is imminent to apply a coating on metal interconnection lines (copper as an illustrative example) that would prevent the diffusion of metal atoms into the silicon and dielectrics around it. In conventional interconnection technologies, a layer of TaN serves as the standard diffusion barrier that also features chemical stability and conformal coating at reduced dimensions. The main disadvantage of TaN coatings is its high electrical resistivity of ^{˜}100-400 μΩcm. In addition, it should be noted that features formed through the deposition of a TaN diffusion barrier layer cannot be scaled down in proportion to the reduced cross-sectional area of respective metal conductor interconnects. Consequently, the resistive surface diffusion barrier consumes an increasingly more dominant surface skin on the metal at higher technology generations.

Improved reliability may be quantified by the mean time to fail (“lifetime”) of metal (copper) interconnections which is dominantly affected by electromigration resulted failure, as described for example in: M. R. Baklanov, C. Adelmann, L. Zhao, and S. De Gendt, “Advanced Interconnects: Materials, Processing, and Reliability,” ECS Journal of Solid-State Science and Technology, vol. 4, no. 1, pp. Y1-Y4, and in references therein, and in G. C. Shwartz, “Handbook of semiconductor interconnection technology” CRC Press, 2006. Electromigration is caused by transfer of linear momentum from electrons moving under strong electric fields to the metal atoms, driving their migration along the direction of electrical current flow. Consequently, copper interconnection lines become thinner “upstream” and thicker “downstream” along the electrical current path—resulting in increased electrical resistance at thinner regions and in increased mechanical strain at the thicker regions. Eventually, the thinner points of reduced cross-sectional area feature high resistance and thus develop increasingly higher temperatures that drive electromigration even faster with positive feedback ending in failure due to metal voids and open circuit breakdown. Electromigration, therefore, puts a limit on the maximal current density driven on the metal wire, per a defined reliability (mean time to fail—MTTF).

There is a need to for better diffusion barrier and capping materials that may provide better conductivity and long-term reliability.

More recently, the emergence on new electronic materials such as graphene has shown potential for use as diffusion barriers in integrated interconnections and as two dimensional electric and thermal conductive layers on surfaces. See for example: R. Mehta et al. Nanoscale, 2017, 9, 1827-1833, R. Mehta, et al. Nano letters, 2015, 15, 2024-2030 and M. Stelzer et al. EEE Journal of the Electron Devices Society, 2017, 5, 416-425. However, crucial obstacles still prevent industrial application of graphene as a new type of diffusion barrier, mainly in the step of in situ graphene synthesis and non-satisfactory properties of the product.

### SUMMARY OF INVENTION

### Technical Problem

The aim of the invention is to provide a method for forming a graphene layer or a graphene patterned layer on a non-metallic surface and in particular on a semi-conductor or a dielectric. The aim of the invention according to certain aspects is to provide a method for forming an effective diffusion barrier e.g., between the non-metal surface and a metal layer, that is thin and more conductive targeting improved reliability. In addition to improved conductivity, improved reliability requires the following conditions: (i) good thermal and chemical stability; (ii) good thermal conductivity; (iii) good adhesion to copper and to dielectrics; (iv) fast, void-free, wafer-scale, high-yield deposition method.

According to a further aspect, an aim of the invention is to provide a method for forming diffusion barrier that may be formed and shaped in dimensions that are in proportion with respective metal interconnects that, in turn, may be formed in coordinated manufacturing steps.

According to yet further aspects of the invention, an aim of the invention is to provide a protective coating and to provide a method of producing a graphene layer that will keep the non-metallic layer or substrate intact. According to this aspect of the invention properties of a graphene layer deposited on the non-metallic layer or substrate provide required properties such as surface conductivity or a diffusion barrier.

According to the invention a method is disclosed for the deposition of a graphene barrier in between a dielectric layer and a metal conductor (e.g., copper), providing for high conductivity and improved barriers between the metallization layers (i.e. the metal interconnects), the dielectric layers and the wafer substrate (e.g. silicon). As such, the method provides for continuing the progress of semiconductor integrated circuit technology. A further advantage of the forming of graphene layers as diffusion barrier layer is their superior metal diffusion blocking capability which has been demonstrated for copper. Thus, providing a highly conductive diffusion barrier layer according to the invention, enables driving higher currents through an interconnection section without passing the maximal current density driven through the metal wire, per the defined reliability.

As noted in the above reference, graphene quality and growth temperature are the important requirements for efficient forming of graphene barriers for copper. As is demonstrated in the examples hereinbelow, the method according to the invention provides for forming high graphene quality at relatively low growth temperature. According to some embodiment of the invention the method is performed at relatively low effective temperature range and provides for controlled graphene quality and controlled wafer temperature. According to the invention graphene diffusion barrier is formed by polymerization of precursors, some of which are novel, that bond to the non-metallic surface (dielectric or semi-conductor), and which may be initiated and controlled, inter alia, by maintaining elevated temperatures or by laser assisted localized heating.

The invention further aims to provide a method for localized forming and shaping of the graphene diffusion barrier layers to form graphene diffusion barrier regions and enabling shaping of diffusion barrier regions in proportional dimensions with respective metal interconnects that may be formed in coordinated manufacturing steps.

### Solution to Problem

In a first aspect the invention provides a method for coating a non-metallic surface comprising the steps of
obtaining at least one graphene molecular precursor comprising a compound A having the molecular formula I

G-X¹ₖY¹ₘY²ₙ formula I:

wherein G is a C₆-C₁₀₀ hydrocarbon component, X¹ is a tethering group capable of covalently binding to the non-metallic surface, Y¹, Y² are independently selected from the group consisting of hydrogen, halogen radical, acidic functional group, a basic functional group or combination thereof and n, m and k are independent integer numbers having a value selected between 1 and 20;
depositing said first graphene molecular precursor on top of the non-metal surface to obtain a surface at least partially coated with the at least one graphene molecular precursor; and
reacting the graphene molecular precursor with a non-metallic surface to form covalent bonds between at least a portion of the X¹ tethering groups and the non-metallic surface to obtain a non-metallic surface covalently linked to graphene molecular precursor; and transforming the deposited first graphene molecular precursor into a surface bound graphene interfacial layer, to obtain a non-metallic surface covered by a graphene layer wherein the dielectric layer being covalently connected to the graphene layer.

According to another aspect, the invention provides a method for coating a non-metallic surface comprising the steps of obtaining a tethering precursor having the molecular formula II

D-X²ₙ formula II:

wherein D is a hydrophobic component, X² is a tethering group capable of covalently binding to the non-metallic surface and n is an integer number having a value selected between 1 and 20;
reacting D-X²n with the surface to obtain a non-metallic surface covalently linked to a hydrophobic layer;
obtaining a graphene molecular precursor G-Y¹ₘY²ₖ wherein G is a C₆-C₁₀₀ hydrocarbon component, Y¹, Y² are independently selected from the group consisting of hydrogen, halogen radical, acidic functional group (A), a basic functional group (B) or combination thereof and m and k are independent integer numbers having a value selected between 1 and 20;
reacting G-Y¹ₘ Y²ₖ with the hydrophobic layer to obtain a graphene self-assembled precursor layer comprising a hydrophobic layer covalently linked to the dielectric layer and covered by a graphene precursor layer; and transforming the deposited first graphene molecular precursor into a surface bound graphene interfacial layer.

In yet another aspect the invention provides a compound having the molecular formula I

G-X¹ₙY¹ₘY²ₖ formula I:

for use as a graphene molecular precursor wherein G is a C₆-C₁₀₀ hydrocarbon component, X¹ is a tethering group capable of covalently binding to the non-metallic surface, Y¹, Y² are independently selected from the group consisting of hydrogen, halogen radical, acidic functional group, a basic functional group or combination thereof and n, m and k are independent integer numbers having a value selected between 1 and 20 for use in a molecular graphene precursor for the formation of a graphene layer wherein the graphene layer is covalently bound to a non-metallic surface.

In a further aspect the invention provides a compound having the molecular formula II

G-X¹ᵢX²ⱼY¹ₘY²ₙ formula II:

wherein G is a C₆-C₁₀₀ hydrocarbon component, X¹ is a tethering group capable of covalently binding to the non-metallic surface, Y¹, Y² are independently selected from the group consisting of hydrogen, halogen radical, acidic functional group, a basic functional group or combination thereof, X² is selected from at least one of: a tethering group to a graphene surface X^{2G}, a tethering group to a metal layer X^{2M}, and a tethering group to a non-metal layer X^{2N}, and l, j, n, m and k are independent integer numbers having a value selected between 1 and 20 for use in a molecular graphene precursor for the formation of a graphene layer wherein the graphene layer is covalently bound to a non-metallic surface.

In a further aspect the invention provides a compound having the molecular formula III

G-Y¹ₘY²ₙ formula III:

wherein G, Y¹, Y², m and n are as defined in as above for use in a molecular graphene precursor for the formation of a graphene layer wherein the graphene layer is covalently bound to a non-metallic surface.

In a further aspect the invention provides a compound having the molecular formula IV

GX²ⱼY¹ₘY²ₙ formula IV:

wherein G, Y¹, Y², m and n, and j and X² are defined as above for use in a molecular graphene precursor for the formation of a graphene layer wherein the graphene layer is covalently bound to a non-metallic surface.

In a yet further aspect, the invention provides a compound having the molecular formula V

GX²ⱼY¹ₘY²ₙ formula V:

wherein G, Y¹, Y², m and n, and j and X² are defined as in claim 40 for use in a molecular graphene precursor for the formation of a graphene layer wherein the graphene layer is covalently bound to a non-metallic surface.

In a further aspect the invention provides a compound having the molecular formula VI

G-X^{2g}ᵢX³ⱼY¹ₘY²ₙ formula VI:

wherein G, Y¹, Y², m and n, defined as above, and j and X^{2g} and X³ are tethering groups to a surface of a graphene coating, defined as in claim 40, being different from each other for use in a molecular graphene precursor for the formation of a graphene layer wherein the graphene layer is covalently bound to a non-metallic surface.

In a further aspect the invention provides a compound having the molecular formula VII

D-X²ₙ formula VII:

wherein D is a hydrophobic component and X² is a tethering group capable of covalently binding to a non-metallic surface and n is an integer number having a number selected between 1 and 20 for use in a molecular graphene precursor for the formation of a graphene layer wherein the graphene layer is self-assembled to a hydrophobic layer, the hydrophobic layer comprising the compound having formula VII, and the hydrophobic layer being covalently bound to the non-metallic surface.

In a further aspect the invention provides a graphene coated non-metallic surface comprising a covalent bond between the graphene and the non-metallic surface or between a molecule bound to the graphene and the non-metallic surface.

In a further aspect the invention provides the graphene coated non-metallic surface comprises at least two layers of graphene.

In a further aspect the invention provides a method for monitoring graphene layer formation during manufacture process of graphene coating of a surface comprising:
obtaining fluorescent microscope photos at intervals during the process;
identifying fluorescence of a graphene molecular precursor as evidence for deposition of graphene molecular precursor;
identifying reduction of fluorescence intensity of graphene molecular precursor as evidence for transformation of the graphene molecular precursor into graphene layer fluorescence incomplete process; and
identifying reaching minimal fluorescence intensity as an end point of the manufacturing process of graphene layer coating of the non-metallic surface.

### BRIEF DESCRIPTION OF THE DRAWINGS

For better understanding of the present invention and to exemplify how it may be implemented in practice, several embodiments are hereby described, which should be interpreted only as non-limiting examples, with reference to the accompanying figures. It is noted that the sizes and scale of the embodiments presented in the figures are exemplary and non-limiting.

It will be appreciated that for simplicity and clarity of illustration, where appropriate, reference numerals have been repeated among the different figures to indicate corresponding or analogous elements. In addition, numerous specific details are set forth to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein.

FIG. 1A depicts a block diagram representing a general method for forming a graphene layer on a non-metallic surface and optional forming interconnections according to an embodiment of the invention.

FIG. 1B depicts a block diagram representing a general method for forming a graphene layer on a non-metallic surface and forming interconnections and/or top layers according to embodiments of the invention.

FIG. 2A and FIG. 2B schematically depict products formed according to the method disclosed in reference to FIG. 1A and FIG. 1B according to an embodiment of the invention.

FIG. 3 depicts a block diagram representing a general method for forming a graphene coating on a hydrophobic layer covalently connected to a non-metallic surface and optional forming interconnections on the graphene layer according to an embodiment of the invention.

FIG. 4A and FIG. 4B schematically depict products formed according to the method disclosed in reference to FIG. 3 according to an embodiment of the invention.

FIG. 5A and FIG. 5B depict Microscope pictures (×50) of a product prepared according to an embodiment of the method disclosed in reference to FIG. 3: (5A) Trenches after UV irradiation of the rubrene layer; (5B) Same location after Au evaporation deposition and lift-off according to an embodiment of the invention.

FIG. 6A and FIG. 6B depict a cross section (made by FIB) SEM figure [HV 5 kV] of one trench of the graphene coated surface and Au line prepared according to an embodiment of the method disclosed in reference to FIG. 3 according to an embodiment of the invention.

FIG. 7 shows an EDS (Energy Dispersive X-Ray Spectroscopy) mapping of one trench in a silicon substrate, produced according to the invention, exhibiting the presence of a thin layer of carbon allotrope on top of the Si substrate and covered by a 86-89 nm wire layer of Au according to an embodiment of the invention.

FIG. 8 shows Raman spectrum scattered from a trench in a prototype produced according to an embodiment of the invention.

### DESCRIPTION OF EMBODIMENTS

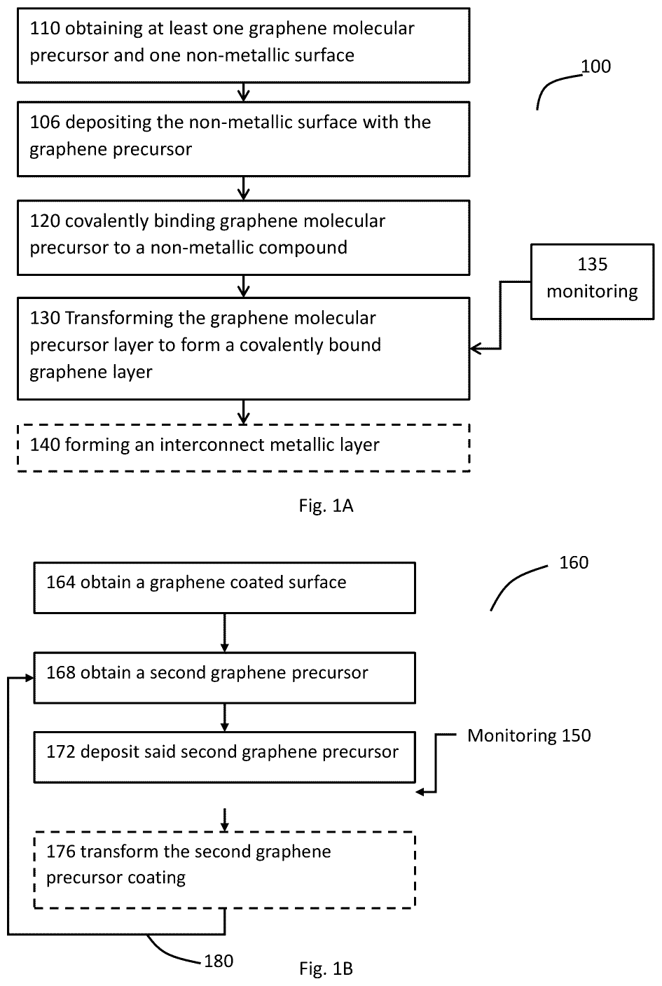

Although the invention is illustrated and described herein as embodied in FIGS. 1 to 8 examples 1 to 3, the invention is not limited to the details shown because various modifications and structural changes may be made without departing from the invention and the equivalents of the claims. However, the compositions construction and method of production or operation of the invention together with additional objects and advantages thereof will be best understood from the following description of specific embodiments when read in connection with the accompanying drawings.

The present invention provides a method for coating a non-metallic surface with graphene layer and provides for a device comprising a non-metallic surface coated with a graphene layer.

Referring to FIG. 1 a general method for forming a graphene layer on a non-metallic surface and optional forming of interconnections, according to an aspect of the invention is disclosed. According to embodiments of the invention, the method comprises obtaining at least one (first) graphene molecular precursor comprising at least one compound A having the molecular formula I

G-X¹ᵢY¹ₘY²ₙ formula I:

wherein G is a C₆-C₁₀₀ aromatic hydrocarbon component, X¹ is a tethering group capable of covalently binding to a non-metallic compound of a non-metallic layer, Y¹, Y² are independently selected from the group consisting of hydrogen, a halogen radical, an acidic functional group, a basic functional group or combination thereof and i m and n are independent integer numbers having a value selected between 1 and 20 (step 110). The sum of i, m and n is equal or less than the number of carbon atoms of component G, and is usually equal or less than the number of hydrogen bound carbons in an unsubstituted component G.

According to an aspect of the invention the compounds of formula I are for use as a graphene molecular precursor for forming a graphene layer on top of a non-metal surface. The component G is the building block of the graphene to be. It is made of an aromatic carbon skeleton which may be small aromatic molecules such as benzene or consisting of several aromatic rings fused to each other (polycyclic aromatic hydrocarbons). The method according to the invention may employ different graphene molecular precursors having different shapes, in attempt to provide high graphene coverage with a minimal number of defects (voids) in the two-dimensional graphene layer. After their deposition on the surface these building block will later on form during a transformation step carbon-carbon bonds between them to generate the two-dimensional graphene network.

According to some embodiments G is a C₁₀-C₁₀₀ polycyclic aromatic hydrocarbon (PAH), optionally comprising heteroatoms selected from silicon, germanium, zinc, sulfur, nitrogen and oxygen. In some embodiments G is selected from the group consisting of rubrene, coronene, p-hexabenzocoronene, hexa-cata-hexabenzocoronene, pentacene, hexaphenylbenzene, perylene, chrysene, pyrene, PAHs of compounds IV-VIII or combinations thereof.

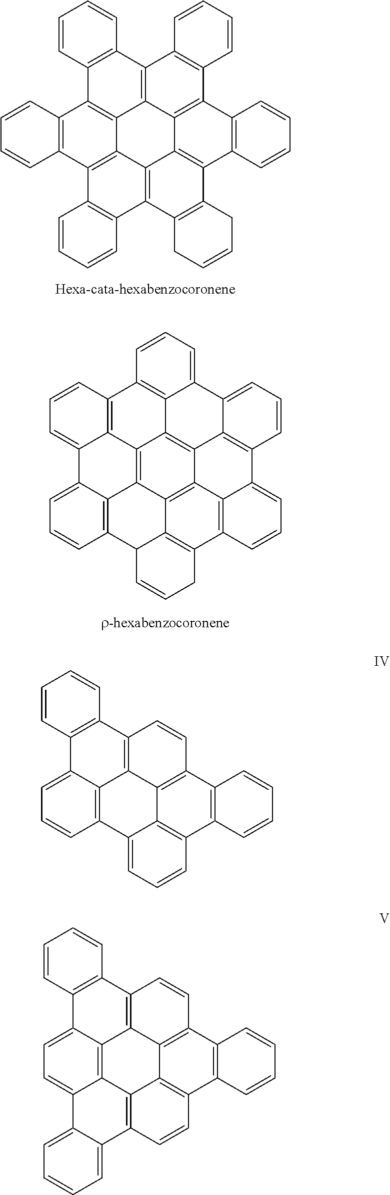

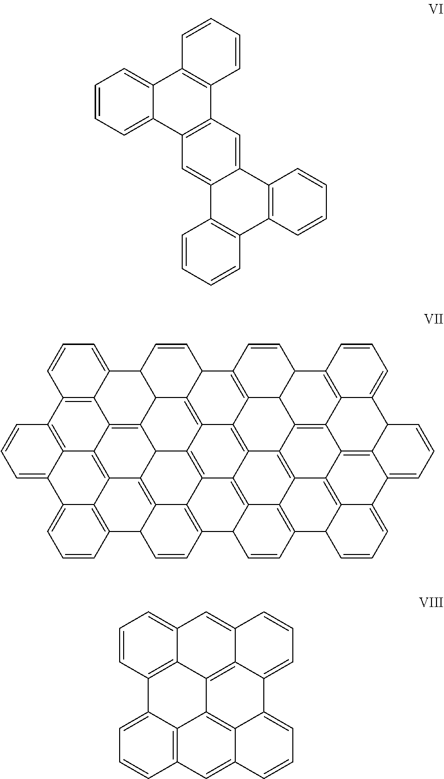

According to some embodiments the non-metallic surface is a silicon surface. According to some embodiments the non-metallic surface is a silicon surface covered by a dielectric layer that can consist of SiO₂.

According to some embodiments X¹ is selected from the group consisting of C₁₋₈ siloxyl, sulfonyl, phosphonate, -, —SiR¹R²R³, —NR⁴R⁵, —R⁵COOR⁶R⁷SH wherein R¹, R², and R³ are independently selected from H, —OH, —Cl, —Br, —F, —I, C₁₋₈ saturated or unsaturated optionally derivatized (by the group consisting of siloxyl, sulfonyl, phosphonate, —SiR¹R²R³, —NR⁴R⁵, —R⁵COOR⁶R⁷SH wherein R¹, R², and R³ are independently selected from H, —OH, —Cl, —Br, —F, —I and combinations thereof) alkyl, and at least one of R¹, R², and R³ is —Cl, —Br, —F or —I; R⁴ and R⁵ are independently selected from H, C₁₋₈ saturated or unsaturated optionally derivatized (by the group consisting of siloxyl, sulfonyl, phosphonate, -, —SiR¹R²R³, —NR⁴R⁵, —R⁵COOR⁶R⁷SH wherein R¹, R², and R³ are independently selected from H, —OH, —Cl, —Br, —F, —I and combinations thereof) alkyl; R⁶ is H or C₁₋₈ saturated or unsaturated optionally derivatized (by the group consisting of siloxyl, sulfonyl, phosphonate, —SiR¹R²R³, —NR⁴R⁵, —R⁵COOR⁶R⁷SH wherein R¹, R², and R³ are independently selected from H, —OH, —Cl, —Br, —F, —I and combinations thereof) alkyl; R⁷ is a bond or C₁₋₈ saturated or unsaturated optionally derivatized alkyl.

The formation of the carbon-carbon bonds between the compounds of the graphene molecular precursor is configured to happen after deposition and formation of a graphene molecular precursor layer (i.e., a layer made of compounds of the graphene molecular precursor before they form a graphene layer). The formation of the carbon-carbon bonds between the compounds of the graphene molecular precursor to form a graphene layer, can be assisted by having the aromatic skeleton (G) bear good leaving functional groups as the Y¹ and Y² groups on the periphery of the G component. For example, Y¹ can be a halide such as —Cl or —Br and Y² can be —H, such that when the graphene molecular precursor layer is transformed into a layer (e.g., by elevated temperatures or by appropriate radiation), a halide from one graphene molecular precursor and a hydrogen from another graphene precursor would leave as HCL or HBr and the two graphene molecular precursors would form a carbon-carbon bond. In another example, Y¹ can be —Cl and radiation of the graphene molecular precursor layer generates carbon-carbon bonds between two carbons (which were linked to —Cl) of two adjacent (same or different) graphene molecular precursor molecules and a Cl₂ molecule is generated.

In some embodiments Y¹ and Y² can be acidic and basic groups, respectively, in order to design the orientation of the graphene molecular precursors with respect to each other, for example that a side bearing acidic functional groups would face a side bearing basic functional groups of another molecule. The basic and acidic functional groups can be on the same molecule (e.g., on different sides of the periphery of the carbon skeleton) or there may a mixture of two different graphene molecular precursors, one bearing acidic functional groups and the other bearing basic functional groups. As will be detailed below, such graphene molecular precursors may be deposited concomitantly or consecutively.

According to some embodiments, the basic functional group is —NR⁴R⁵, and the acidic functional group is selected from —R⁵COOH, —R⁷SO₂, —R⁷PO₃H₂, and salts thereof wherein R⁴, R⁵ and R⁷ are as defined above.

According to some embodiments G-X¹ₙY¹ₘY²ₖ is selected from: tetrakis(trichlorosilyl)rubrene, tetrakis(trichlorosilyl)difluororubrene, tetrakis(trichlorosilyl)coronene, hexa-peri-tetrakis(trichlorosilyl)difluorohexabenzocoronene, hexa-peri-hexakis(triethoxysilyl)dibromobenzocoronene, p-tetrakis(trichlorosilyl)difluorohexaphenylbenzene, hexachloropyrene and mixtures thereof. It is noted that the scope of the invention is not restricted to specific positions of the functional groups on the aromatic skeleton of each exemplary molecule. In some embodiments, the graphene molecular precursor G-X¹ₙY¹ₘY²ₖ is selected from compounds IX, X and mixtures thereof:

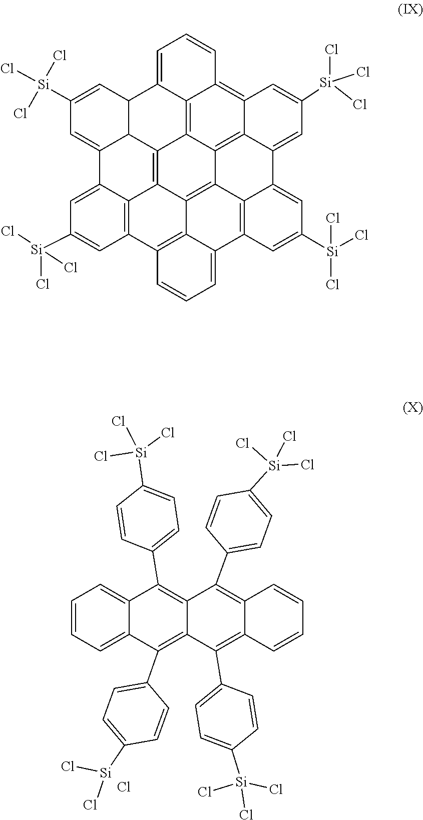

The term “tethering group” refers in the context of the invention to a functional group which is capable of forming a covalent bond by means of a chemical reaction with molecular entities being part of the non-metallic surface. The formation of the covalent bond results in the covalent bonding between the molecule which comprises the tethering group (e.g., the graphene molecular precursor) and a (non-metallic) surface or a layer.

The term “non-metallic layer” or a “non-metallic surface” refers to a layer that is composed of a semi-metal material, a semiconductor material or an insulator (dielectric) material or a surface thereof. The semiconductor material can be a silicon (Si), germanium (Ge), silicon germanium (SiGe), silicon doped with carbon (Si:C), silicon germanium doped with carbon (SiGe:C) silicon (Si), germanium (Ge), silicon germanium (SiGe), silicon doped with carbon (Si:C), silicon germanium doped with carbon (SiGe:C), gallium nitride (GaN), indium gallium nitride (InGaN), aluminum gallium nitride (AlGaN). Galium arsenide phosphor (GaAsP), aluminum gallium indium phosphor (AlGaInP), gallium phosphor (GaP), aluminum gallium phosphor (AlGaP), gallium arsenide (GaAs), aluminum gallium arsenide (AlGaAs), Zinc selenium (ZnSe), Zinc oxide (ZnO), gallium oxide (GA₂O₃), and combinations thereof.

In some embodiments a dielectric layer is present atop the semiconductor material, e.g., N type or P type doped silicon. The dielectric layer may be an oxide, nitride or oxynitride material. In some embodiments the dielectric material is selected from the group consisting of silicon containing materials, such as SiO2, Si3N4, SiOxNy, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides.

The term “graphene” refers an allotrope of carbon consisting of a single layer of carbon atoms in which the carbon atoms are generally connected by sp² bonds and forming a ‘honeycomb’ arrangement. The graphene may be contaminated, e.g., with hetero atoms such as Si, Ge or Sn. Hydrogen atoms may be covalently bonded to the peripheral carbon atoms of the single layer or alternatively be replaced by functional groups which in turn may covalently connect the graphene layer to adjacent surfaces. These functional groups and contaminations may in general form a small percent of defects in the graphene idealized structure and aromatic character without significantly changing its conductivity or ability to form a diffusion barrier. When referring to the formation of graphene layers the number of graphene layers refers to the number of single atom graphene layers, however, as the context may imply, a layer structure of an element or a device may comprise several layers of graphene or of other materials, wherein each of the graphene layers may comprise a plurality of single atom-thick graphene layers.

The term “molecular precursor” refers to at least one compound that participates in a chemical reaction that produces a new compound (a product). The molecular precursor may include several compounds (i.e, a mixture) which collectively form the product. Specifically, the term “graphene molecular precursor” refers to compounds that after reaction, their main carbohydrate backbone become part of a graphene layer.

According to some embodiments of the invention the method comprises obtaining at least one (first) graphene molecular precursor comprising at least one compound selected from the group consisting of compound A as defined above and compound B having molecular formula II

G-X¹ᵢX²ⱼY¹ₘY²ₙ formula II:

wherein, G¹, Xᵢ¹, Yₙ¹, Yₘ², l, m, and n are defined as above, and X² is selected from at least one of: a tethering group to a graphene surface X^{2G}, a tethering group to a metal layer X^{2M}, and a tethering group to a non-metal layer X^{2N}, and j is an independent integer number having a value selected between 1 and 20.

According to some embodiments, X² is X^{2N} a non-metal tethering group, that is a tethering group capable of covalently binding to a non-metallic compound of a non-metallic layer. According to such embodiments, X² may be independently selected from any group selectable for X¹ as defined above with respect to compound A.

According to some embodiments, X² is X^{2M} a metal tethering group, i.e., a functionalized tethering group that is tailored to connect a graphene precursor to a surface of a metal material by a covalent bond. According to such embodiments, X^{2M} is selected from the group consisting of —R¹COOR², —R¹SO₃R², —R¹PO₃H₂, —R¹COH, —NR³R⁴ and —R¹SH wherein R¹ is selected from a bond, C₁₋₈ saturated or unsaturated, substituted or unsubstituted alkyl; R² is H or C₁₋₈ saturated or unsaturated, substituted or unsubstituted alkyl, R³ and R⁴ are independently selected from H, C₁₋₈ saturated or unsaturated optionally derivatized alkyl. When the metal the tethering group is to be bonded to is titanium then X^{2M} may further be selected from —R¹SiOH and R¹SiCl₃. In this regard, it is noted that the selection of the tethering group X^{2M} may take into consideration the affinity of a functional group to the specific metal the tethering group is to be bonded to.

According to some embodiments, X² is X^{2G} a graphene tethering group, i.e., a functionalized tethering groups that is tailored to connect a graphene precursor to a surface of a graphene layer or to a tethering group of a compound of an adjacent graphene molecular precursor by a covalent bond or pi-interaction. According to such embodiments, X^{2G} is selected from the group consisting of C₆-C₂₀ aryl unsubstituted or substituted by an electron withdrawing group, C₆-C₂₀ substituted or unsubstituted heteroaryl, —R¹SiOH, R¹SiCl₃, —R¹X, —NR³R⁴, —R¹COOH, —R¹SO₃R², and —R¹PO₃H₂, wherein R¹ is selected from a bond, C₁₋₈ saturated or unsaturated, substituted or unsubstituted alkyl, X is selected from —OH, —Cl, —Br, —F, or —I, R³ and R⁴ are independently selected from H, C₁₋₈ saturated or unsaturated optionally derivatized C₁₋₈ alkyl.

According to some embodiments, the electron withdrawing group is selected from the group consisting of a halide, —CN, —NO₂, —CHO, —COOR², —C(═O)R⁵ wherein R² is H or C₁₋₈ saturated or unsaturated, substituted or unsubstituted alkyl R⁵ is C₁₋₈ saturated or unsaturated, substituted or unsubstituted alkyl.

For example, a graphene tethering group that is part of a first graphene molecular precursor can be an acidic functional group. This acidic group may be sterically available (after formation of a graphene coating from a deposited first graphene molecular precursor) to react with a basic functional group of a compound of a second graphene molecular precursor which is deposited on top of the previously formed graphene coating to form a bond (e.g., amid bond between an amine and a carboxylic acid).

In another example a graphene tethering group that is part of a first graphene molecular precursor can be a silicon halide group (e.g., trichlorosilyl), which may react with a silanol functional group of a compound of a second graphene molecular precursor which is deposited on top of the previously formed graphene coating (that was formed from the first graphene molecular precursor) to form a siloxane bond.

According to some embodiments, compound B (having formula II: G-X¹ᵢX²ₘY¹ₘY²ₖ) bears tethering groups to a non-metal surface when X² is X^{2N} and is selected from: tetrakis(trichlorosilyl)rubrene, tetrakis(trichlorosilyl)difluororubrene, tetrakis(trichlorosilyl)coronene, tetrakis(trichlorosilyl)difluorohexabenzocoronene, p-tetrakis(trichlorosilyl)difluorohexaphenylbenzene, hexachloropyrene and mixtures thereof. It is noted that the scope of the invention is not restricted to specific positions of the functional groups on the aromatic skeleton of each exemplary molecule.

According to an aspect of the invention the compounds of formula II are for use as a graphene molecular precursor for forming a graphene layer on top of a non-metal surface. According to an aspect of the invention, step 110 of the method (obtaining the first graphene molecular precursor comprising at least one of compound A or compounds B, and obtaining the non-metal surface) further comprises obtaining a first graphene molecular precursor comprising at least one of compound C and compound D; compound C having formula III

G-Y¹ₘY²ₙ; and formula III:

compound D having the molecular formula IV

GX²ⱼY¹ₘY²ₙ formula IV:

wherein G, X², Y¹ and Y², and j, m and n are defined as above. Compounds

According to an aspect of the invention the compounds of formula III or formula IV are for use as a graphene molecular precursor. According to some embodiments, the first graphene molecular precursor may comprise several compounds wherein each in turn may comprise several of: (i) compounds having tethering groups for covalently bonding to the surface of the non-metal layer to form a coating, (ii) compounds having tethering groups for covalently bonding to the surface of the non-metal layer to form a coating, and additional tethering groups that may be utilized in following process steps, and (iii) compounds having no tethering groups. The combination of different compounds provides important advantages which will be elaborated further below. According to embodiments where the graphene molecular precursor is a mixture of compounds, several compound mixtures may form the graphene molecular precursor and may be mixed in advance (concomitantly) or used consecutively in interspersed manner (one after the other).

According to some embodiments the first graphene molecular precursor is a mixture comprising compound C and at least one of compound A and compound B, and the mole ratio between the combined number of molecular precursors of compound A and compound B and compound D and the molecular precursor of compound C being between 50:1 and 1:5000, preferably between 10:1 and 1:1000 and more preferably between 1:5 and 1:500. According to some embodiments said mole ratio is lower than 1:200.

According to embodiments, said first graphene molecular precursor is deposited on top of the non-metal surface to obtain a surface at least partially coated with the at least one graphene molecular precursor. According to certain embodiments, the deposition of the graphene precursor on the non-metallic layer is performed by dip coating or by vacuum deposition. According to some embodiments the deposited graphene molecular precursor forms a graphene molecular precursor layer on the non-metallic surface. According to some embodiments, the deposition excludes deposition by CVD.

The term “dip coating” relates to a coating process that may comprise, immersion of a substrate in a solution, a start-up step in which the substrate has remains inside the solution for a while before being pulled out of the solution, a deposition step in which a thin layer deposits itself on the substrate while it is pulled out of the solution, and an evaporation step in which solvent is evaporated from the thin layer formed the surface of the substrate.

The term “vacuum deposition” relates to a family of processes used to deposit layers of material atom-by-atom or molecule-by-molecule on a solid surface. These processes typically operate at pressures well below atmospheric pressure (i.e., vacuum).

The deposition of the new layer of graphene molecular precursors can be done by dip coating of the substrate in a solution comprising the graphene molecular precursor or by vacuum deposition (e.g., and more specifically, atomic layer deposition (ALD)) of the graphene molecular precursor (by sublimation or evaporation of a solution comprising the graphene molecular precursor).

The term “atomic layer deposition (ALD)” relates to thin-layer deposition techniques based on the sequential use of a gas-phase chemical process. In general terms ALD also refers to molecular layer deposition. Differentiated from general CVD, ALD and MLD are thin-layer deposition techniques that, by relying on self-terminating surface chemistry, enable the control of the amount of deposited material down to the atomic or molecular level. Thus, thin layers, down to a single layer of atoms may be formed. ALD and MLD are deposition techniques based on the sequential use of a gas-phase chemical process, wherein each sequential step is also referred to as a cycle. Typically, ALD use one or two (molecular) precursors (also called “reactants”). These precursors are deposited on the surface of a material/substrate and potentially react with the surface of the material, one at a time in a sequential, self-limiting, manner, to form chemical bonds with the surface of the material. The chemical bonds may be weak bonds e.g., adhesion bonds or strong bonds such as covalent bonds. Typically, a cycle begins with a pulsated release of at least one of the precursors from a heated container into a reaction chamber, followed by an incubation (“wait”) period in which at least part of the released precursor is deposited on the surface of the material/substrate positioned inside the reaction chamber, wherein in some cases the released precursor reacts with other deposited chemical moieties on the surface of the substrate or with the surface of the substrate.

According to some embodiments, thin layer deposition may be ALD, which in turn may be any one of thermal ALD, Plasma enhanced ALD (PEALD) also referred to as plasma-assisted ALD or radical-enhanced ALD, hot-wire ALD and photo assisted ALD. Advantages of these ALD processes include precise control the thickness, fill factor and composition of the formed graphene molecular precursor layer/coating.

Referring back to FIG. 1A, and to step 120, the deposited graphene molecular precursor is reacted with the non-metallic surface (e.g., a dielectric layer) to form covalent bonds between at least a portion of the X¹ tethering groups and the non-metallic/dielectric to obtain a non-metallic layer covalently linked to a graphene molecular precursor layer (step 120). The reaction between the tethering group and the non-metallic surface may occur spontaneously as the graphene molecular precursor is coated/deposited on the non-metallic surface. For example, when the tethering group is trichlorosilyl and the surface contains hydroxysilane groups then siloxyl bond are spontaneously formed between the graphene molecular precursor and the non-metallic surface. According to some embodiments maintaining elevated temperatures is required to initiate and maintain the reacting of the tethering group and the non-metallic surface.

According to certain embodiments the non-metallic layer onto which the graphene molecular precursor is bound, is positioned on top of a wafer chip comprising a semi-conductor substrate (e.g., a silicon substrate) having electric circuit elements formed on its upper surface.

The graphene molecular precursor may be selected such as to enable vacuum deposition, being volatile at conventional vacuum chambers operating at pressures not higher than 1e⁻³ Torr, in some embodiments not higher than 1e⁻⁶ Torr. Correspondingly G, the hydrocarbon component of graphene molecular precursor may contain less than 100 carbon atoms, in some embodiments less than 90, 80, 70, or 60 carbon atoms. According to some embodiments the graphene molecular precursors evaporates from solution. According to some embodiments the molecular graphene precursor sublimes from solid state, e.g., from a powder given the appropriate low pressure and temperature conditions.

Referring in more detail to vacuum deposition, precision Atomic Layer Deposition (ALD) may be used, a process in which a series of pulses of vaporized reactants (in particular molecular precursors) or catalysts are inserted into a reaction chamber in which a substrate is positioned, to react at the surface of the substrate (e.g. a non-metallic surface, and in particular a wafer or an already existing graphene surface) in a controlled manner and to precisely control the thickness, fill factor and composition of the formed graphene molecular precursor layer. According to some embodiments, for the formation of the layer of covalently bound molecular precursors, one or more pulses of vaporized first graphene molecular precursor are inserted into the chamber. Thus, precise control of the thickness of the deposited layer of the graphene molecular precursor may be achieved enabling consistent control of the following stages of the process. According to some embodiments, during the series of pulses one or more pulses of vaporized second graphene molecular precursor are interleaved with the pulses of the first precursor. According to some embodiments the second graphene molecular precursor having different hydrocarbon component G or different tethering groups X¹ₘ, e.g., to control the fill factor on the substrate surface. According to some embodiments the first and second graphene molecular precursors have different functional groups Y¹ₙ and Y²ₖ, e.g., to control the uniformity and defect ratio of the formed graphene layers. According to embodiments more than two graphene molecular precursors may be used. According to some embodiments, following or in parallel to the deposition of the graphene molecular precursors, graphene molecular precursors are reacted with the non-metallic surface to form covalent bonds between at least a portion of the tethering groups and the non-metallic surface to obtain a non-metallic surface covalently linked to graphene molecular precursor. According to some embodiments the reaction between the graphene molecular precursors and the non-metal surface is catalyzed by elevated temperature in the reaction chamber. According to some embodiments the formation of such bonds happens in parallel to a transformation of the deposited graphene molecular precursors to a graphene layer as described below. According to some embodiments, a catalyst may be incorporated into the process; during the series of pulses one or more pulses of the vaporized catalyst are inserted into the chamber and at least partially deposited on the surface of the substrate. According to such embodiments the catalyst may be a metal catalyst selected from Pd, Pt, Cu, Au, Ni, W and Co, or a mixture thereof.

Following the forming of the graphene molecular precursor layer transforming the graphene molecular precursor layer into a surface bound graphene interfacial layer (step 130) is performed. According to some embodiments the transforming is achieved by maintaining the deposited graphene molecular precursor layer at elevated temperatures. According to some embodiments of the invention the process of the formation of the covalently bound graphene layer from the deposited (and optionally covalently bound) graphene precursor is performed at relatively low temperatures, below 500° C. or below 400° C. and in some embodiments, below 350° C. below 300° C., below 250° C. or below 200° C.

According to some embodiments, transforming the deposited graphene molecular precursor (step 130) is initiated and/or maintained by radiating the graphene molecular precursor layer. According to some embodiments, a first radiation source is used to radiate at wavelengths (light frequencies) and intensity sufficient for conversion of the graphene precursor layer into a graphene layer to obtain a dielectric or non-metallic layer covered by a graphene layer wherein the dielectric or non-metallic layer being covalently connected to the graphene layer (step 130). According to certain embodiments radiation of 20,000 mJ/cm² at 375 nm is sufficient. According to some embodiments, radiation as low as 500 mJ/cm² at 375 nm is sufficient. According to certain embodiments, radiation of between 500 mJ/cm² to 20,000 mJ/cm² at 375 nm is employed. According to certain embodiments radiation of 500, 600, 700, 1000, 2000, 3000, 4000, 5000, 6000, 7000, 8000, 9000, 10000, 15000 or 20,000 mJ/cm² at wavelengths in the range 325 to 450 nm is employed. According to certain embodiments the first light source may be a LED or a laser. According to such embodiments, the wavelengths of the first light source may be selected to be preferably absorbed in the graphene precursor layer. Selection of the wavelengths of the first radiation source may be based on an the weighted wavelength dependent absorption ratio defined as the ratio between the absorption coefficient of the graphene molecular precursor relative to the absorption coefficient of the non-metallic layer or the absorption coefficient of a semi-conductor layer that is part a wafer at the specific wavelength of interest and weighted, inter alia, by the wavelength specific spectral power and by the relative absorption coefficient. According to certain embodiments, the absorption ratio is larger than 10 and preferably larger than 100. According to certain embodiments the first radiation source is a UV radiation source comprising wavelengths predominantly shorter than 450 nm. Selecting such UV radiation source has important advantages, including potential localization of the radiation to due to the short wavelengths (e.g., supplemented by use of high numerical aperture, low aberration optics) and efficient use of the energy through a photo-excitation process which directly leads to the formation of reactive moieties that react to form the graphene layer. According to some embodiments, at one of (i) the radiation frequency and (ii) the radiated region, are selected such that 90% of the absorbed radiation energy (absorbed by the coated substrate and the deposited graphene molecular precursor layer) is absorbed by the graphene precursor layer or the graphene precursor.

According to some embodiments process temperature may be controlled by controlling the temperature in a process chamber or by locally controlling the temperature in the region that is exposed to the radiation from the first radiation source and in particular by controlling the temperature in the graphene precursor layer in the region that is exposed to the radiation from the first radiation source. This can be accomplished for example by a second radiation source selected to locally irradiate a region of the coated substrate, optionally, in coordinated fashion with radiation of said region of the graphene precursor layer by the first irradiation source. The wavelengths of such second radiation source may be selected to have the absorption ratio (between absorption coefficient of the graphene precursor and the absorption coefficient of the non-metallic layer or the absorption coefficient of a semi-conductor layer that is part a wafer) higher than 10, in some embodiments higher than 100 and in some embodiments, higher than 1000. For example, in case of a graphene precursor layer formed on top of silicon wafer, the second radiation source may be selected to provide light at wavelengths longer than 1.3 micron and in some embodiments shorter than 1.6 micron, wavelengths in which a silicon wafer is relatively transparent. Due to their availability laser and LED with wavelength around 1.5 micron may be a convenient selection. An advantage of the use of a coordinated combination of localized heating and localized photoexcitation is the ability to precisely localize the formation of the graphene layer.

Additionally, or alternatively, the temperature in the reaction chamber, during the polymerization process is monitored by common methods available in the art, for example, by positioning, on the non-metallic surface, labels containing photo thermal switching dyes, indicative of the maximal temperature on the surface. An example of such labels are non-reversible temperature labels marketed by Omega Engineering Inc. of Norwalk, CT, USA. An infra-red camera or a thermocouple may also be used to monitor the temperature as known in the art.

Alternatively, in certain embodiments, the formation of the covalently bound graphene layer from the covalently bound graphene precursor layer may be performed by irradiation with a first radiation source with sufficient intensity in the IR region and in particular at wavelengths between 1.3 micron and 1.5 micron wherein the first radiation source has an absorption ratio higher than 10, in some embodiments higher than 100 and, in some embodiments, higher than 1000.

According to certain embodiments, the formation of covalently bound graphene layer may be monitored by Raman spectrography. According to such embodiments, a third radiation source is used to generate Raman scattering, typically in the visible or IR wavelength range. Raman scattering is used to characterize the presence of graphene and may provide signals indicative of the regions comprising the un-polymerized graphene precursor layer. Accordingly, in some embodiments, Raman scattering signal indicative of a presence of a full layer of graphene within a detected region (or indicative of elimination of the graphene precursor) is used to indicate the state of the polymerization of graphene precursor layer and when appropriate, to arrest the radiation of light of the first or second source which drive the generation of the graphene layer. According to some embodiments, Raman spectra may also be used to monitor the quality of the formed graphene layer using for example the intensity ratio of the respective spectral lines/peaks indicative of the formation of the graphene layer and the exhaustion of the precursor. As for example disclosed in Araujo P. T. et al. Materials Today 2012, 15, 98-109, defect density (number of defects per cm²) may be estimated directly from this ratio. Alternatively, coverage ratio or coverage continuity of the graphene layer may be used to quantify its quality, measuring the percent of the area of the graphene layer that is without defect. However, this measure should be used carefully in the right context as for example, in large, say 100 cm², transparent electrode 99% coverage can be a 1 cm² defect or a hundred 1 mm² defects—two extreme cases which might have very different implications on the quality of the product. According to certain embodiments, the second and third radiation sources may be one and the same source. According to certain embodiments, Raman scattering which is dependent on the temperature of the scattering material is used to probe the temperature of the irradiated graphene precursor layer or the formed graphene layer, to monitor and control their respective temperatures, thereby enabling better control of process temperature and higher, more repeatable quality of the formed graphene layer.

According to further aspects of the invention additional monitoring of the process may be performed to increase its reliability and consistency, to perform quality assurance and to detect an authenticity signature of a produced layer being part of a device. According to certain embodiments, the formation of covalently bound graphene layer may be monitored by fluorescence microscopy or spectrography. According to some embodiments, monitoring graphene layer formation during manufacture process of graphene coating of a surface comprises (i) obtaining fluorescent microscope photos at intervals during the process, (ii) identifying fluorescence of a graphene molecular precursor as evidence for deposition of graphene molecular precursor, (iii) identifying reduction of fluorescence intensity of graphene molecular precursor as evidence for transformation of the graphene molecular precursor into graphene layer fluorescence during an incomplete process and (iv) identifying reaching minimal fluorescence intensity as an end point of the manufacturing process of graphene layer coating of the non-metallic surface. According to further embodiments fluorescent microscope photos before and after each step of the process of manufacture may be obtained and used, e.g., as reference. According to some embodiments integrated collection of a fluorescent signal may be performed instead of or in parallel to taking microscope photos.

According to some embodiments measuring surface contact angle of the substrate and identifying typical surface contact angle measurement may be used as evidence for formation of a desired surface after each step of the manufacturing process.

In embodiments in which a metal catalyst is used, traces of the catalyst remain in the formed graphene layer coated non-metallic layer, either as dispersed traces (e.g., atomic layers or nanoclusters) between the graphene layer and the non-metallic layer or on top of the graphene layer. Thus, spectroscopic signature of the catalyst traces which may be detected (e.g., in expected locations) and may serve as authenticity signature of a produced graphene layer on a non-metallic surface, being part of a device.

In some embodiments, after the graphene layer is obtained small aromatic molecules such as benzene, biphenyl, phenanthrene, anthracene, naphthalene, optional derivatized by Y¹ and Y² groups defined above, or mixtures thereof can be deposited on top of the graphene layer followed by incubation at elevated temperatures and/or by further irradiation in order to fill any defects in the graphene layer which may have formed.

After completing a first graphene layer, a new layer of graphene molecular precursors, being same or different from the graphene molecular precursors of the preceding layer may be deposited on top of the formed graphene layer. According to some embodiments, the method of the invention incorporates several separate steps in which a graphene molecular precursor is used to form a plurality of graphene layers, whereas the first graphene molecular precursor or a second graphene molecular precursor may be used to form respective layers. Although, first and second graphene molecular precursor may be different, some of the steps pertaining to their composition preparation or use may be similar, and for clarity, as will be understood from the context, will be disclosed together.

Reference is made to FIG. 1B illustrating of forming of at least two graphene layers over a non-metal surface, the method comprising obtaining a graphene coated non-metal surface comprising a graphene layer (optionally an interfacial layer) bound to the surface of the non-metal as disclosed in reference to FIG. 1A (step 164).

According to some embodiments the method comprises obtaining a second graphene molecular precursor comprising at least one compound selected from the group consisting of compound A, compound B, compound C, compound D, compound E having molecular formula V

G-X³ᵢY¹ₘY²ₙ, and formula V:

compound F having molecular formula VI

G-X²ᵢX³ⱼY¹ₘY²ₙ formula VI:

wherein, G, X², Y¹, Y² are i, j, m and n are defined as above, X³ is a tethering group to the surface of the graphene coating selected from the group defined for X^{2G} and being different than the tethering group X^{2G} selected for compound B or D; (step 168).

According to some embodiments at least one compound of the second graphene molecular precursor is functionalized by group X² is X^{2G} being a graphene tethering group (whereas it should be noted that “having tethering groups” or “functionalized by tethering groups” are interchangeable). According to these embodiments the method further comprising depositing the second graphene molecular precursor on top of the graphene coated non-metal surface to obtain a graphene coated material wherein the first graphene coating being at least partially coated with the second graphene molecular precursor (step 172) and transforming the deposited second graphene precursor into a top graphene coating to obtain a graphene coating comprising at least a graphene interfacial layer and a top graphene coating (step 176), the graphene interfacial layer being bound to the surface of the non-metal. According to some embodiments at least one compound of the first graphene molecular precursor is functionalized by group X^{2G} or at least one compound of the second graphene molecular precursor is functionalized by group X^{2G} or both, wherein the graphene interfacial layer being bound to the top graphene coating.

According to some embodiments, tethering groups in different layers may interact with each other. Thus for example, (i) a first graphene molecular precursor comprises a compound comprising X^{2G} being a basic group, e.g., —NR³R⁴, may be deposited in a first coating and a second graphene molecular precursor comprises a compound comprising X^{2G} being an acidic group —R¹COOH may be deposited in a second coating, or (ii) a first graphene molecular precursor comprises a compound comprising X^{2G} being an acidic group —R¹COOH may be deposited in a first coating, and the second graphene molecular precursor in a second coating comprises a compound comprising X^{2G} being a basic group X² is —NR³R⁴. According to some embodiments, the acidic group is selected from —R¹COOH and the basic group is selected from NR³R⁴. R¹, R³ and R⁴ are as defined above. Thus, according to an additional aspect of the invention the compounds of formula V or formula VI are also for use as a graphene molecular precursor for forming a graphene layer on top of a non-metal surface.

The deposition and transforming steps can be iterated as much as needed in order to obtain a desired number of graphene layers or coatings. The graphene molecular precursors can be the same or different in each iteration. According to some embodiments the method further comprises the steps of obtaining a second graphene molecular precursor, depositing of said second graphene molecular precursor on top of the first graphene coated metal material and transforming the deposited graphene molecular precursor to a top graphene coating are repeated, as indicated by arrow 180 in FIG. 1B, to obtain a graphene coating comprising at least three graphene coatings, the graphene interfacial layer being bound to the non-metal surface. For example, the number of coatings may be at least 4 coatings or at least 6 coatings. According to some embodiments the number of graphene layers formed in the thus repeated process is 2 to 12 graphene coating layers, according to some embodiments the number is 2 to 6.

According to some embodiments of the method of the invention, following the formation of one or more graphene layers as described in reference to either FIG. 1A or FIG. 1B, a metal layer or an interconnect metallic layer is deposited (i.e. metallization) on top of the covalently bound graphene layer (step 140). According to embodiments metallization may be performed using conventional vacuum deposition processes. According to embodiments, metallization may be performed by different approaches either directed at a patterned metallization layer or a non-patterned metallization layer. According to some embodiments, the pattern may be a two-dimensional pattern, e.g., printing a pattern on a flat surface or a three-dimensional pattern, e.g., comprising the metallization of trenches and vias forming an interconnect pattern that can connect between different layers of a device.

The term “interconnect” refers to a structure which electrically links, two or more points or nodes. It may encompass one or more separate conduction paths such as wires, vias, waveguides, passive and/or active components.

According to some embodiments at least one of the compounds of the second graphene molecular precursor comprises a compound having a tethering group X^{2M}, forming a top layer of coating that is configured to form bonds with a metal, and the method further comprising depositing a metal on top of the top graphene coating, to obtain a layered structure comprising a graphene coating bound to the non-metal surface and bound to a metal layer on top of the graphene coating. According to some embodiments targeted at the forming of interconnects, this arrangement of layers enables the use of thin interconnects of metals such as copper, aluminum or ruthenium within a complex BEOL section of a VLSI semiconductor device while mitigating issues such as metal diffusion into the non-metallic (dielectric) layers.

According to some embodiments the non-metal material is a first non-metal material, at least one of the compounds of the second graphene molecular precursor comprises a compound having a tethering group X^{2N} and further comprising the step of depositing a second non-metal having a surface being same as, or different from the first non-metal surface on top of the top graphene coating (step 140 modified to deposit a non-metal layer instead of a metal layer), to obtain a layered structure comprising a graphene coating bound to the non-metal surface and bound to the second non-metal material layer on top of the graphene coating.

The terms top and bottom as used herein refer to the order in which the different layers are deposited, thus for example a bottom layer of graphene may be formed on the side of a trench in a non-metal substrate, and a metal layer deposited thereafter on the exposed side of the graphene layer (the side which is distal to the non-metal substrate) is referred to as being ‘on top’ of the graphene layer while its orientation is on the side of the trench.

According to some embodiments, the deposited graphene molecular precursor layer is maintained at elevated temperatures to initiate and/or maintain the transforming of the graphene molecular precursor layer to form a second graphene layer as described above. According to some embodiments, after the deposition step, the graphene molecular precursors are irradiated to form a second graphene layer as described above. The deposition and irradiation process can be iterated as much as needed in order to obtain a desired number of graphene layers. The graphene molecular precursors can be the same or different in each iteration.

According to certain embodiments, a metal pattern is formed on the graphene pattern to form an interconnect. According to certain embodiments screen printing using metal composite paste may be used to form metallization layer on top of a patterned graphene layer. In an example application the method may be used to form a graphene layer pattern on surfaces of silicon solar cells on which metal (e.g., copper or copper/cobalt mixture) may be deposited to form a wiring pattern of interconnects (AKA contact fingers) deposited as described above. Such application provides for better electrical performance and lower cost metallization compared to conventional use of silver contact fingers.

According to some embodiments the graphene layer coated non-metallic surface is for use in a wide range of applications such as, without wishing to be limited thereto, an interconnection, in a device selected from the group consisting of back end of lines (BEOL), nano-electromechanical device, photovoltaic cells, and transparent conductive electrodes, sensors and graphene transistors.

According to some embodiments of the method the non-metallic surface remains intact during the transformation of the graphene precursor into a graphene layer. According to some embodiments, retaining the substrate and the graphene molecular precursors at mild reaction conditions such as relatively low elevated temperatures e.g., at below 500° C., 400° C. 300° C. or 200° C., and low pressure provides for maintaining the substrate intact, avoiding damages which occur in prior art graphene coating mechanisms. Examples of such damages may be reactions with residual contaminates, diffusion of doped elements in the case of doped semi-conductor substrate, defect growth and edged defect propagation for crystalline and polycrystalline materials. According to some embodiments, retaining the substrate at mild radiation conditions provides for maintaining the substrate intact e.g., by preventing extensive local temperature increase or material deterioration at a result of extensive exposure to ionizing radiation.

According to certain embodiments the method further comprises depositing a conducting wire on the graphene layer, to obtain a graphene interlayered interconnection comprising a graphene diffusion barrier between the bottom of the conducting wire and a dielectric layer of the non-metallic surface and optionally between the sidewalls of the conducting wire and the dielectric layer of the non-metallic surface. In an example, the graphene precursor is deposited in a trench etched in a silicon substrate to form a groove shaped graphene precursor layer covalently bound to the dielectric layer (e.g., SiO₂) of the non-metallic surface (e.g., silicon) in the trench and then polymerized to form a groove shaped graphene layer. Metal deposited on top of graphene layer in the trench is surrounded by the graphene from bottom and sides and the graphene layers form a barrier between the sidewalls of the metal wire and the non-metallic substrate.

In some embodiments the graphene layer is used as a conductive layer in a desired application.

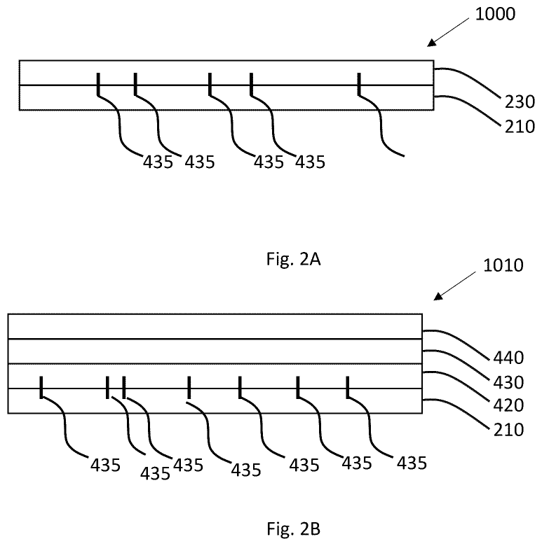

Reference is made to FIG. 2A and FIG. 2B, schematically illustrating products (1000 and 1010) of the method as illustrated with respect to FIGS. 1A and 1B. FIG. 2A schematically illustrates a product (1000) comprising a semiconductor substrate (210), and a graphene layer (230) where the non-metallic surface of the semi-conductor 210 in this example is covalently linked by covalent bonds 435 to the graphene layer 230. The graphene layer 230 may comprise one single atom-thick (interfacial) layer, or a plurality of single atom-thick graphene layers. FIG. 2B schematically illustrates a product (1010) comprising a semiconductor substrate (210), a dielectric layer (420) and a graphene layer (430) where the non-metallic surface, a dielectric in this example, is covalently linked to the graphene layer through covalent bonds (435). As indicated above, the graphene layer (430) may comprise one single atom-thick (interfacial) layer or a plurality of single atom-thick graphene layers. On top of the graphene layer (430) a metallization layer (e.g., interconnects) is deposited (440).

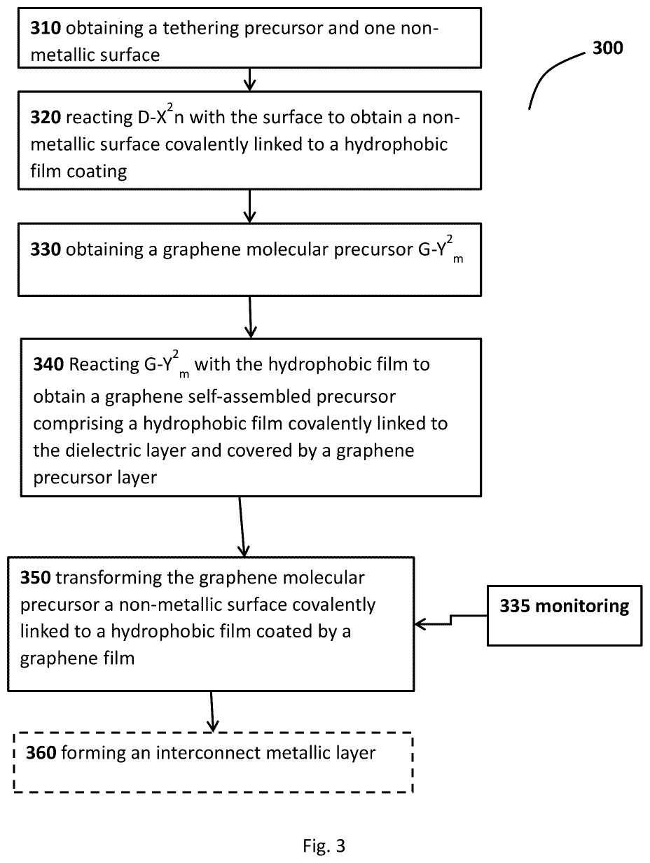

According to a further aspect of the invention a method for coating a non-metallic surface is disclosed, the method comprising, inter alia, steps of forming non-metallic surface covalently linked to a hydrophobic layer coating. The method is illustrated in detail with respects to FIG. 3 and is detailed hereinbelow. According to certain embodiments the method comprises the steps of obtaining a tethering precursor having the molecular formula VII (step 310)

D-X²ₙ Formula VII

wherein D is a hydrophobic component and X² is a tethering group capable of covalently binding to the non-metallic surface and n is an integer number having a number selected between 1 and 20,
reacting D-X²ₙ with the surface to obtain a non-metallic surface covalently linked to a hydrophobic layer coating (step 320), obtaining a graphene molecular precursor of formula III

G-Y¹ₘY²ₖ Formula VIII

wherein G is a C₆-C₁₀₀ aromatic hydrocarbon component, Y¹ and Y² are independently selected from the group consisting of hydrogen, halogen radical, acidic functional group, a basic functional group or combination thereof and m and k are independent integer number having a value selected between 1 and 20 (step 330). According to an aspect of the invention the compounds of formula VII and/or formula VIII are for use as a graphene molecular precursor for forming a graphene layer on top of a non-metal surface. Reacting G-Y¹ₘY²ₖ with the hydrophobic layer to obtain a graphene self-assembled precursor comprising a hydrophobic layer covalently linked to the dielectric layer and covered by a graphene precursor layer (step 340), and, transforming the deposited first graphene molecular precursor into a surface bound graphene interfacial layer (step 350). According to some embodiments, transforming is initiated and maintained by maintaining the deposited first graphene molecular precursor at elevated temperatures.

According to some embodiments, transforming is performed by radiating the graphene molecular precursor layer by a first radiation source at wavelengths and intensity sufficient for conversion of the graphene precursor into graphene to obtain a non-metallic surface covalently linked to a hydrophobic layer coated by a graphene layer (step 350). According to certain embodiments radiation of 20,000 mJ/cm² at 375 nm is sufficient. According to some embodiments radiation of 500 mJ/cm² at 375 nm is sufficient. According to certain embodiments radiation of between 500 mJ/cm² to 20,000 mJ/cm² at 375 nm is employed. According to certain embodiments radiation of 500, 600, 700, 1000, 2000, 3000, 4000, 5000, 6000, 7000, 8000, 9000, 10000, 15000 or 20,000 mJ/cm² at wavelengths in the range 300 nm to 450 nm is employed. According to some embodiments, the radiating of the coated substrate can be combined with incubating the substrate coated with the graphene molecular precursor at elevated temperatures.

According to certain embodiments, D in formula VII is a C₆-C₁₀ aromatic hydrocarbon radical such as phenyl. According to some embodiments D is a C₅-C₁₀ aromatic hydrocarbon radical optionally comprising heteroatoms selected from silicon, sulfur, nitrogen and oxygen such as pyridinyl or furanyl.

According to certain embodiments, group X² in formula II is defined as X¹ defined above.

According to certain embodiments, the basic functional group in formula VIII is selected from —NR⁴R⁵ wherein R⁴ and R⁵ are independently selected from —H,C₁₋₈ saturated or unsaturated alkyl, and the acidic functional group is selected from —R⁶COOH, —R⁷SO₂, —R⁸PO₃H₂, wherein R⁶, R⁷ and R⁸ are independently a C₁₋₈ saturated or unsaturated optionally derivatized (by the group consisting of siloxyl, sulfonyl, phosphonate, -, —SiR¹R²R³, —NR⁴R⁵, —R⁵COOR⁶R⁷SH wherein R¹, R², and R³ are independently selected from H, —OH, —Cl, —Br, —F, —I and combinations thereof) alkyl.

According to specific embodiments, G- of formula VIII is defined as G of formula I.

According to certain embodiments the total energy of the radiation applied on the second graphene precursor is below 10 KJ per cm². in some embodiments less than 1 KJ per cm² or less than 0.1 KJ per cm²

As noted with respect the embodiment of the invention described in reference to FIG. 1A and with respect to the polymerization of the first graphene precursor using radiation, a radiation source or sources is/are selected for initiating, driving, and controlling the polymerization. First or second radiation source(s) selected with respect to the embodiments described in reference to FIG. 3 are, mutatis mutandis, the same wherein the radiation source' or sources' wavelengths are selected from UV light below 450 nm and IR light above 1.3 micron. Accordingly, the respective materials and radiation sources' wavelengths are selected such that the absorption ratio between the second graphene precursor of formula VII and the dielectric layer or the non-metallic substrate is, or are, in the case of a radiation source predominantly in the UV range, larger than 10, or, in some embodiments, larger than 100, and in the case of a radiation source in the IR range, larger than 100, or, in some embodiments, larger than 1000.

According to some respective embodiments, and in further reference to FIG. 3, monitoring and control (step 335) comprises detecting the Raman scattering while radiating with IR light, characterizing presence of graphene and arresting the radiation of light when the Raman scattering is indicative of a presence of a full layer of graphene at the irradiated location.

According to some embodiments monitoring and controlling (step 335) comprises detecting the Rayleigh scattering while radiating with IR light and adjusting the intensity of the IR radiation in order to maintain maximum temperature at below 400° C. Alternatively, monitoring and controlling the temperature of the graphene precursor layer comprises controlling the temperature in the reaction/vacuum chamber, the use of switching photo-thermal dyes or alternative thermal sensing.

According to some embodiments of the method of the invention, an interconnect metallic layer is deposited on top of the covalently bound graphene layer (step 360), mutatis mutandis, similar to step 140 in FIG. 1A. According to embodiments metallization may be performed using, inter alia, conventional vacuum deposition processes, silk screen printing or ink-jet printing.

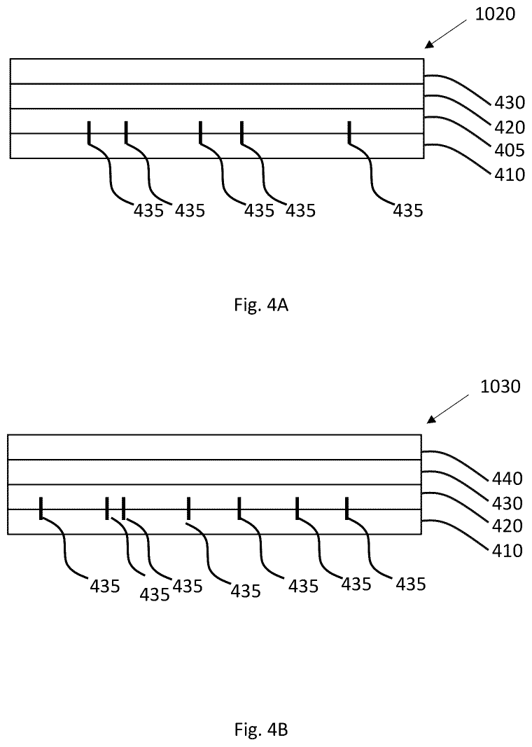

Reference is made to FIG. 4A and FIG. 4B, schematically illustrating products of the method as illustrated with respect to FIG. 3. FIG. 4A schematically illustrates a product (1020) comprising a semiconductor substrate (410), a dielectric layer (405), a covalently bound hydrophobic layer (420) and a graphene layer (430) where the non-metallic surface, a dielectric in this example, is covalently linked through covalent bonds (435) to a hydrophobic layer coated by a graphene layer.

FIG. 4B schematically illustrates a product (1030) comprising a semiconductor substrate (410), a covalently bound hydrophobic layer (420) and a graphene layer (430) where the non-metallic surface is a semi-conductor in this example and is covalently linked through covalent bonds (435) to a hydrophobic layer coated by the graphene layer. On top of the graphene layer a metallization layer (interconnects) is deposited (440).

According to yet a further aspect, the invention provides a compound having the molecular formula of any one of formulae I to VIII as described above being useful as a precursor to form a graphene Layer.

According to another aspect the invention provides a graphene coated non-metallic surface (e.g., dielectric layer) comprising a covalent bond between the graphene and the non-metallic surface or between at least one (type of) molecule bound to the graphene and to the non-metallic surface. The molecule covalently bound to the non-metallic surface may be bound to the graphene through a covalent bond. The molecule covalently bound to the non-metallic surface may be bound to the graphene through a n-T bond. The molecule covalently bound to the non-metallic surface may be bound to the graphene through an ionic bond with a functional group of the graphene.

In some embodiments the graphene coated non-metallic surface is characterized by at least one of: (i) a graphene defect density equal to or lower than 10¹² defects per cm², in some embodiments lower than 10¹¹ defects per cm², in some embodiments lower than 1 ppm and (ii) essentially free of catalytic metal residue, in some embodiments comprising up to atomic layers of metal catalyst, in some embodiments comprising up to nano-clusters of metal (Pd, Pt, Au Ni, W, Co, Cu) (iii) graphene coverage higher than 90%, 95%, 98%, 99% or 99.5%.

The term “essentially free of catalytic metal residue” means herein that the product comprises less than 3% w/w of metal, in some embodiments less than 1%, in some embodiments less than 100 ppm, in any form of pure metal (layers, film, clusters etc.).

According to some embodiments the invention provides a graphene coated interconnection comprising at least two layers of graphene. According to some embodiments the graphene coated interconnection comprises between 2-6 layers of graphene.

According to some embodiments the invention provides a graphene coated interconnection which is characterized by an effective conducting wire fill factor of at least 90%.

According to some embodiments, the invention provides a graphene coated interconnection (wherein the interconnect is formed atop the graphene layer) wherein the conducting wire is copper characterized by at least one of (i) a graphene defect density equal to or lower than 10¹² defects per cm², in some embodiments lower than 10¹¹ defects per cm², in some embodiments lower than 1 ppm (ii) comprising at least two layers of graphene and (iii) an effective Copper fill factor of at least 70%.

According to a further aspect the invention provides a semiconductor device comprising the graphene coated non-metallic surface.

The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. Embodiments were chosen and described in order to best explain the principles of the invention and the practical application, and to enable others of ordinary skill in the art to understand the invention for various embodiments with various modifications as are suited to the particular use contemplated. To the extent that the following description is of a specific embodiment or a particular use of the invention, it is intended to be illustrative only, and not limiting of the claimed invention.

The corresponding structures, materials, acts, and equivalents of all means or steps plus function elements in the claims appended to this specification are intended to include any structure, material, or act for performing the function in combination with other claimed elements as specifically claimed.

References in the specification to “one embodiment”, “an embodiment”, etc., indicate that the embodiment described may include a particular aspect, feature, structure, or characteristic, but not every embodiment necessarily includes that aspect, feature, structure, or characteristic. Moreover, such phrases may, but do not necessarily, refer to the same embodiment referred to in other portions of the specification. Further, when a particular aspect, feature, structure, or characteristic is described in connection with an embodiment, it is within the knowledge of one skilled in the art to combine, affect or connect such aspect, feature, structure, or characteristic with other embodiments, whether or not such connection or combination is explicitly described. In other words, any element or feature may be combined with any other element or feature in different embodiments, unless there is an obvious or inherent incompatibility between the two, or it is specifically excluded.

It is further noted that the claims may be drafted to exclude any optional element. As such, this statement is intended to serve as antecedent basis for the use of exclusive terminology, such as “solely,” “only,” and the like, in connection with the recitation of claim elements or use of a “negative” limitation. The terms “preferably,” “preferred,” “prefer,” “optionally,” “may,” and similar terms are used to indicate that an item, condition or step being referred to is an optional (not required) feature of the invention.

The singular forms “a,” “an,” and “the” include the plural reference unless the context clearly dictates otherwise. The term “and/or” means any one of the items, any combination of the items, or all of the items with which this term is associated.

As will be understood by one skilled in the art, for any and all purposes, particularly in terms of providing a written description, all ranges recited herein also encompass any and all possible sub-ranges and combinations of sub-ranges thereof, as well as the individual values making up the range, particularly integer values. A recited range (e.g., weight percents or carbon groups) includes each specific value, integer, decimal, or identity within the range. Any listed range can be easily recognized as sufficiently describing and enabling the same range being broken down into at least equal halves, thirds, quarters, fifths, or tenths. As a non-limiting example, each range discussed herein can be readily broken down into a lower third, middle third and upper third, etc.

As will also be understood by one skilled in the art, all ranges described herein, and all language such as “up to”, “at least”, “greater than”, “less than”, “more than”, “or more”, and the like, include the number(s) recited and such terms refer to ranges that can be subsequently broken down into sub-ranges as discussed above.

### EXAMPLES

### Example 1

Narrow trenches (2 μm) were made on Si/SiO₂ wafer by photolithography following by Reactive Ion Etching (RIE) with CHF₃+O₂. Self-assembly monolayers of Phenyltrichlorosilane (PhTS) were deposited in the trenches by immersion in solution of 10 mM PhTS in Hexane for 60 min, rinsing with hexane and iso-propyl alcohol (IPA) and baking for 2 min at 110° C. Then, thin layer of graphene's precursor aromatic molecules was deposited in those trenches by dip-coating in 1 mg/ml Rubrene in Toluene at 80° C., following drying 2 min at 110° C. Graphene synthesis was performed by exposing the thin layer of the graphene precursor to 10 J/cm² of a 375 nm laser. Then a layer of thickness of 100 nm of Au was deposited by evaporation deposition (e-beam evaporator, Temescal) followed by photoresist lift-off with acetone to obtain Au lines with a graphene diffusion barrier. Finally, the substrate was exposed to UV at 375 nm for 10 min in mask-aligner.

### Characterization:

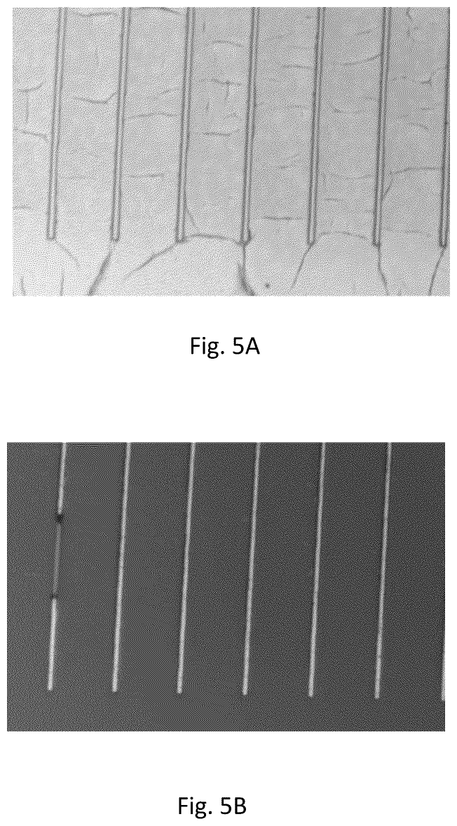

Contact angle measurements and fluorescent microscope photos evidenced the formation of the desired layers after each step. by providing typical contact angle values for each type of surface and fluorescent image for a fluorescent surface vs. non-fluorescent surface FIG. 5A shows a microscope picture (×50) of trenches after UV irradiation of the rubrene layer and FIG. 5B shows the same location/region, at the same magnification, after Au evaporation and lift-off of the photoresist. The Au lines that are deposited on the graphene layer in the trenches are clearly seen. This is evidence that the graphene layer which carries the Au lines remain in place after the lift off treatment.

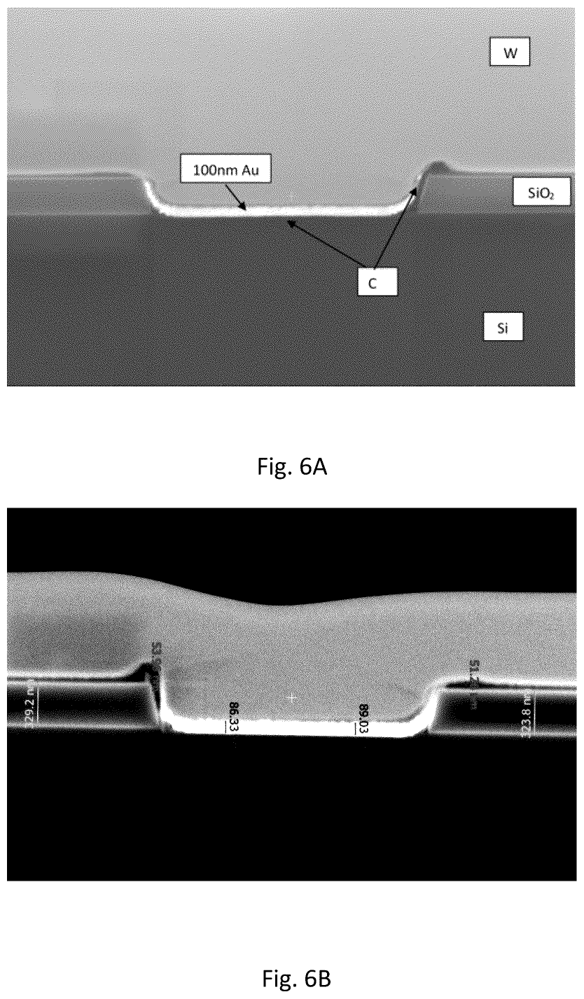

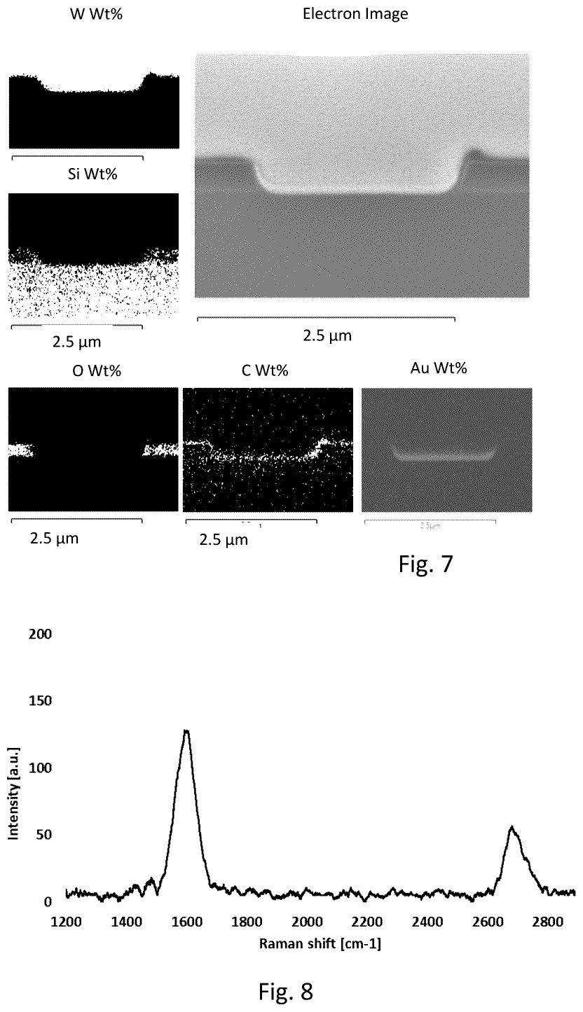

FIG. 6A and FIG. 6B show a cross section (made by Focused ion beam FIB) SEM [Date May 11, 2021, Magnification ×50,000; WD, 4.0 mm; HV 5.0 KV; current: FIG. 6A 0.8 nA, FIG. 6B 0.10 nA; det TLD, tilt: FIG. 6A 55°, FIG. 6B 38°; mode SE] of one trench of the product and FIG. 7 shows an Energy Dispersive X-Ray Spectroscopy (EDS) mapping of the same trench, exhibiting the presence of a thin layer of carbon allotrope on top of the Si substrate and covered by a 86-89 nm wire layer of Au.

Referring to FIG. 8, Raman spectra (532 nm) scattered from a trench, shows indicative of formation of a carbon allotrope typical to several layers of graphene in the trench.

Transport measurement of the product can be performed with back-gated graphene field-effect transistors. To accurately obtain the carrier mobility, the contact resistance R_{contact}, which is comparable to the graphene channel resistance R_{channel}, should be taken into account. The carrier mobility p can be extracted by fitting the the model described in Kim, S.; Nah, J.; Jo, I.; Shahrjerdi, D.; Colombo, L.; Yao, Z.; Tutuc, E.; Banerjee, S. K. Appl. Phys. Lett. 2009, 94, 062107.

### Example 2

A graphene molecular precursor of Formula I such as trichlorosilylhexabenzocoronene can be prepared by brominating a p-hexabenzocoronene using the NBS reagent (AIBN, CCl₄) followed by reaction with tetrachlorosilane under inert conditions to obtain trichlorosilylhexabenzocoronene (G=hexabenzocoronene; X=—SiCl₃; Y¹=Y²=—H). By using precaculated reagent ratio, a dibromo p-hexabenzocoronene can be obtained on the bromination step and having only one of the bromides substituted by a trichlorsilyl group to obtain bromo(trichlorosilyl)hexabenzocoronene (G=hexabenzocoronene; X=—SiCl₃; Y¹=—Br; Y²=—H). Isolation and characterization of the products can be performed by standard purification (e.g. chromatography, recrystallization) and analytical techniques (e.g. NMR, IR, MS, m.p) available in the art.

### Example 3

ALD can be used to deposit a graphene molecular precursor such as trichlorosilylhexabenzocoronene onto Si/SiO₂ wafer. ALD in a Savannah S200 Model by Cambridge nanotech is examplified. Heater 1 can be set to 250° C. Heater 2 can be set to 220° C. The system can be stabilyzed for 600 sec. Depositing repeated 50 times (“pulses”). Valve 0 is opened for 0.015 sec and wait period between pulses is 8 seconds. A constant rate of deposition of trichlorosilylhexabenzocoronene layers can be achieved.

Graphene synthesis can be performed by exposing the thin layer of the graphene molecular precursor to 10 J/cm² of a 375 nm laser. Consequently, the Si/SiO₂ is covered by the graphene layer wherein the Si/SiO₂ layer being covalently connected to the graphene layer.

### Example 4

ALD can be used to deposit the graphene molecular precursor trichlorosilylhexabenzocoronene and hexachloropyrene onto Si/SiO₂ wafer. ALD in a Savannah S200 Model by Cambridge nanotech is examplified. Heater 1 can be set to 250° C. Heater 2 can be set to 220° C. The system can be stabilized for 600 sec. Depositing repeated 50 times (“pulses”). Valve 0 is opened for 0.015 sec and wait period between pulses is 8 seconds. A constant rate of deposition of trichlorosilylhexabenzocoronene layers can be achieved.

Following the deposition of the trichlorosilylhexabenzocoronene, the process can be repeated with a second graphene molecular precursor being hexachloropyrene, having the latter fill in voids which are left after the deposition of the former.

Graphene synthesis can be performed by exposing the thin layer of the graphene molecular precursor to 10 J/cm² of a 375 nm laser. Consequently, the Si/SiO2 is covered by the graphene layer wherein the Si/SiO2 layer being covalently connected to the graphene layer.

### Example 5

ALD of a graphene coating on a surface of a silicon wafer can be performed using Savana S100 Veeco and the following sequence:

Place mixture of 1:100 triethoxysilylbenzene/hexabromobenzene in a precursor reservoir.

Place a Silicon wafer with thin Cu layer sample in the reactor under nitrogen atmosphere in the reactor chamber. Set nitrogen flow to 20 sccm.

Set the temperatures in the precursor reservoir, the manifold leading from the reservoir to the reaction chamber and in the reaction chamber respectively to 80° C., 150° C. and 200° C. Stabilize for 10 minutes with 20 sccm nitrogen flow.

Evacuate the reaction chamber to 0.05 Torr,

Perform 8 cycles of 4 bursts of precursor from the reservoir to the reaction chamber, wherein each burst comprises a series of 10 pulses of 15 msec with a wait period of 1 sec between the pulses and a wait of 20 sec between consecutive bursts. Between the cycles wait for 5 min for precursor incubation and transforming into graphene coating.

Purge the reaction chamber by a flow of nitrogen for 20 sec at 20 sccm and cool the system to room temperature.

Deposition of the precursor on the surface can be characterized by XPS and the formation of graphene layer can be characterized by performing Raman Spectroscopy.

### Example 6

ALD of a graphene coating on a surface of a silicon wafer using a Ru catalyst provided in an organo-metallic complex can be performed using Savana S100 Veeco and the following sequence:

Place a mixture of 1:100 triethoxysilylbenzene/hexabromobenzene, dissolved in toluene 1 mg/ml in a graphene molecular precursor reservoir.

Place a Silicon wafer in the reactor under Nitrogen atmosphere in the reactor chamber. Set nitrogen flow to 20 sccm.

Set the temperatures in the graphene molecular precursor reservoir to 70° C., in the Ru precursor reservoir to 70° C., in a H2O reservoir to 30° C., in the manifold leading from the graphene molecular precursor reservoir to the reaction chamber to 150° C. and in the reaction chamber to 180° C. Stabilize for 10 minutes with 20 sccm nitrogen flow.

Evacuate the reaction chamber to 0.05 Torr,

Perform 8 cycles of 4 bursts of graphene precursor from the reservoir to the reaction chamber wherein each burst comprises a series of 10 pulses of 15 msec with a wait period of 5 sec between the pulses and a wait of 20 sec between consecutive bursts.

Perform Ru catalyst deposition. Provide a 100 msec pulse of Ru(DMBD)(CO)₃, wait 5 sec, purge the manifold and chamber by N₂ flow for 15 sec, provide a H₂O pulse for 30 msec. Wait 5 seconds for exposure of the Ru catalyst complex to H₂O to initiate the catalyst (i.e., break the organo-metallic complex). Purge the chamber (from H₂O) for 15 second by N₂ flow.

Wait for 5 min for precursor incubation and transforming into graphene coating.

Purge the reaction chamber by a flow of nitrogen for 20 sec at 20 sccm and cool the system to room temperature.

1.-55. (canceled)

56. A method for coating a non-metallic surface comprising the steps of
obtaining at least one graphene molecular precursor comprising a compound A having the molecular formula I
G-X¹ₖY¹ₘY²ₙ formula I:
wherein G is a C₆-C₁₀₀ hydrocarbon component, X¹ is a tethering group capable of covalently binding to the non-metallic surface, Y¹, Y² are independently selected from the group consisting of hydrogen, halogen radical, acidic functional group, a basic functional group or combination thereof and n, m and k are independent integer numbers having a value selected between 1 and 20;
depositing said first graphene molecular precursor on top of the non-metallic surface to obtain a surface at least partially coated with the at least one graphene molecular precursor; and
reacting the graphene molecular precursor with a non-metallic surface to form covalent bonds between at least a portion of the X¹ tethering groups and the non-metallic surface to obtain a non-metallic surface covalently linked to graphene molecular precursor; and
transforming the deposited first graphene molecular precursor into a surface bound graphene interfacial layer,
to obtain a non-metallic surface covered by a graphene layer wherein the non-metallic surface being covalently connected to the graphene layer.

57. The method of claim 56, wherein the first graphene molecular precursor further comprising at least one compound B having formula II
G¹-X¹ᵢX²ⱼY¹ₘY²ₙ formula II:
wherein, G is a C₆-C₁₀₀ hydrocarbon component, X¹ is a tethering group capable of covalently binding to the non-metallic surface, Y¹, Y² are independently selected from the group consisting of hydrogen, halogen radical, acidic functional group, a basic functional group or combination thereof, X² is selected from at least one of:
a tethering group to a graphene surface X^{2G},
a tethering group to a metal layer X^{2M}, and
a tethering group to a non-metal layer X^{2N}
and l, j, n, m and k are independent integer numbers having a value selected between 1 and 20.

58. The method of claim 56, wherein at least one of the following hods true:
(i) G is a C₁₀-C₁₀₀ polycyclic aromatic hydrocarbon (PAH), optionally comprising heteroatoms selected from silicon, sulfur, nitrogen and oxygen;
(ii) X¹ is selected from the group consisting of C₁₋₈ siloxyl, sulfonyl, phosphonate-SiR¹R²R³, —NR⁴R⁵, —R⁵COOR⁶R⁷SH wherein R¹, R², and R³ are independently selected from H, —OH, —Cl, —Br, —F, —I, C₁₋₈ saturated or unsaturated optionally derivatized alkyl, and at least one of R¹, R², and R³ is —Cl, —Br, —F or —I; R⁴ and R⁵ are independently selected from H, C₁₋₈ saturated or unsaturated optionally derivatized alkyl; R⁶ is H or C₁₋₈ saturated or unsaturated optionally derivatized alkyl; R⁷ is a bond or C₁₋₈ saturated or unsaturated optionally derivatized alkyl;
(iii) the basic functional group is selected from the group consisting of —NR⁴R⁵ wherein R⁴ and R⁵ are independently selected from —H,C₁₋₈ saturated or unsaturated alkyl, and the acidic functional group is selected from —R⁶COOH, —R⁷SO₂, —R⁸PO₃H₂, wherein R⁶, R⁷ and R⁸ are independently selected from a bond, a C₁₋₈ saturated or unsaturated optionally derivatized alkyl;
(iv) compound A is selected from: tetrakis(trichlorosilyl)rubrene, tetrakis(trichlorosilyl)difluororubrene, tetrakis(trichlorosilyl)coronene, tetrakis(trichlorosilyl)difluorohexabenzocoronene, p-tetrakis(trichlorosilyl)difluorohexaphenylbenzene and hexachloropyrene; and
(v) the method further comprising depositing a layer of the graphene precursor on top of the non-metallic surface by atomic layer deposition.

59. The method of claim 57 wherein at least one of the following holds true:
(i) X^{2G} is selected from the group consisting of C₆-C₂₀ aryl unsubstituted or substituted by an electron withdrawing group, C₆-C₂₀ substituted or unsubstituted heteroaryl, —R¹SiOH, R¹SiCl₃, —R¹X, —NR³R⁴, —R¹COOH, —R¹SO₃R², and —R¹PO₃H₂, wherein R¹ is selected from a bond, C₁₋₈ saturated or unsaturated, substituted or unsubstituted alkyl, X is selected from —OH, —Cl, —Br, —F, or —I, R³ and R⁴ are independently selected from H, C₁₋₈ saturated or unsaturated optionally derivatized C₁₋₈ alkyl; X²M is selected from the group consisting of —R¹COOR², —R¹SO₃R², —R¹PO₃H₂, —R¹COH, —NR³R⁴ and —R¹SH wherein R¹ is selected from a bond, C₁₋₈ saturated or unsaturated, substituted or unsubstituted alkyl; R² is H or C₁₋₈ saturated or unsaturated, substituted or unsubstituted alkyl, R³ and R⁴ are independently selected from H, C₁₋₈ saturated or unsaturated optionally derivatized alkyl; and X^{2N} is selected from the group consisting of C₁₋₈ siloxyl, sulfonyl, phosphonate, -, —SiR¹R²R³, —NR⁴R⁵, —R⁵COOR⁶R⁷SH wherein R¹, R², and R³ are independently selected from H, —OH, —Cl, —Br, —F, —I, C₁₋₈ saturated or unsaturated optionally derivatized (by the group consisting of siloxyl, sulfonyl, phosphonate, —SiR¹R²R³, —NR⁴R⁵, —R⁵COOR⁶R⁷SH wherein R¹, R², and R³ are independently selected from H, —OH, —Cl, —Br, —F, —I and combinations thereof) alkyl, and at least one of R¹, R², and R³ is —Cl, —Br, —F or —I; R⁴ and R⁵ are independently selected from H, C₁₋₈ saturated or unsaturated optionally derivatized (by the group consisting of siloxyl, sulfonyl, phosphonate, —SiR¹R²R³, —NR⁴R⁵, —R⁵COOR⁶R⁷SH wherein R¹, R², and R³ are independently selected from H, —OH, —Cl, —Br, —F, —I and combinations thereof) alkyl; R⁶ is H or C₁₋₈ saturated or unsaturated optionally derivatized (by the group consisting of siloxyl, sulfonyl, phosphonate, —SiR¹R²R³, —NR⁴R⁵, —R⁵COOR⁶R⁷SH wherein R¹, R², and R³ are independently selected from H, —OH, —Cl, —Br, —F, —I and combinations thereof) alkyl; R⁷ is a bond or C₁₋₈ saturated or unsaturated optionally derivatized alkyl;
(ii) the first graphene molecular precursor further comprising at least one of compound C having formula III
G-Y¹ₘY²ₙ; and formula III:
compound D having the molecular formula IV
GX²ⱼY¹ₘY²ₙ; and formula IV:
(iii) the method further comprising obtaining a second graphene precursor comprising at least one compound selected from the group consisting of compound A, compound B, compound C, compound D,
compound E having molecular formula V
G-X³ᵢY¹ₘY²ₙ, and formula V:
compound F having molecular formula VI
G-X^{2g}ᵢX³ⱼY¹ₘY²ₙ formula VI:
wherein, G is a C₆-C₁₀₀ hydrocarbon component, X³ is a tethering group to the surface of the graphene coating being different than the tethering group X^{2g}, Y¹, Y² are independently selected from the group consisting of hydrogen, halogen radical and —COOH and i, j, m and n are independent integer numbers having a value selected between 1 and 20; and
depositing the second graphene molecular precursor on top of the graphene coating of the graphene coated non-metal surface to obtain a graphene coated material wherein the graphene coated non-metal surface being at least partially coated with the second graphene molecular precursor; and
transforming the deposited second graphene precursor into a top graphene coating to obtain a graphene coated non-metal surface comprising at least a graphene interfacial layer and a top graphene coating, the graphene interfacial layer being bound to the surface of the non-metal.

60. The method of claim 59 wherein at least one of the following holds true:
i) at least one compound of the first graphene molecular precursor is functionalized by group X^{2G};
ii) at least one compound of the second graphene molecular precursor is functionalized by group X^{2G};
wherein the graphene interfacial layer being bound to the top graphene coating; and
iii) the steps of obtaining a second graphene molecular precursor, depositing of said second graphene molecular precursor on top of the graphene coating and transforming the deposited graphene molecular precursor to a top graphene coating are repeated to obtain a graphene coating comprising at least three graphene coatings, the graphene interfacial layer being bound to the non-metal.

61. The method of claim 56 further comprising at least one of: (i) detecting the Raman scattering while radiating with a second radiation source, IR light, characterizing presence of graphene and arresting the radiation of light when the Raman scattering is indicative of a presence of a full layer of graphene; (ii) measuring contact angle of the surface; and (iii) detecting fluorescence of the surface by a fluorescence microscope.

62. The method of claim 56 further comprising maintaining the temperature of the non-metallic surface at below 400° C.

63. The method of claim 56 wherein the non-metallic surface remains intact during the transforming of the graphene precursor and formation of graphene layer.

64. The method of claim 56 further comprising depositing a metal forming an interconnect wire pattern on the graphene layer pattern, to obtain a graphene coated interconnection comprising a graphene diffusion barrier between the bottom of a conducting wire and a dielectric layer of the non-metallic surface and optionally between the sidewalls of the conducting wire and the dielectric layer of the non-metallic surface.

65. A method for coating a non-metallic surface comprising the steps of
obtaining at least one first graphene molecular precursor comprising at least one compound B having formula II
G¹-X¹ᵢX²ⱼY¹ₘY²ₙ formula II:
wherein, G is a C₆-C₁₀₀ hydrocarbon component, X¹ is a tethering group capable of covalently binding to the non-metallic surface, Y¹, Y² are independently selected from the group consisting of hydrogen, halogen radical, acidic functional group, a basic functional group or combination thereof, X² is selected from at least one of:
a tethering group to a graphene surface X^{2G},
a tethering group to a metal layer X^{2M}, and
a tethering group to a non-metal layer X^{2N}
and l, j, n, m and k are independent integer numbers having a value selected between 1 and 20;
depositing said first graphene molecular precursor on top of the non-metal surface to obtain a surface at least partially coated with the at least one graphene molecular precursor; and
transforming the deposited first graphene molecular precursor into a surface bound graphene interfacial layer,
to obtain a non-metallic surface covered by a graphene layer wherein the dielectric layer being covalently connected to the graphene layer.

66. The method of claim 65 wherein at least one of the following holds true:
(i) transforming comprises maintaining the temperature of the non-metallic surface at above 200° C. and below 400° C.;
(ii) transforming comprises radiating the graphene molecular precursor layer by a first radiation source at wavelengths and intensity sufficient for conversion of the graphene precursor into graphene to obtain a non-metallic surface covalently linked to a hydrophobic layer by a graphene layer, the radiation source wavelengths are selected from UV light below 450 nm and IR light above 1.3 micron; and
(iii) at least one of the radiation frequency and the radiated region are selected such that 90% of the absorbed radiation energy is absorbed by the graphene precursor layer or the second graphene precursor.

67. The method of claim 66 wherein at least one of the radiation frequency and the radiated region are selected such that 90% of the absorbed radiation energy is absorbed by the graphene precursor layer or the second graphene precursor.

68. A method for coating a non-metallic surface comprising the steps of
obtaining a tethering precursor having the molecular formula II
D-X²ₙ formula II:
wherein D is a hydrophobic component, X2 is a tethering group capable of covalently binding to the non-metallic surface and n is an integer number having a value selected between 1 and 20;
reacting D-X²n with the surface to obtain a non-metallic surface covalently linked to a hydrophobic layer;
obtaining a graphene molecular precursor G-Y¹ₘY²ₖ wherein G is a C₆-C₁₀₀ hydrocarbon component, Y¹, Y² are independently selected from the group consisting of hydrogen, halogen radical, acidic functional group, a basic functional group or combination thereof and m and k are independent integer numbers having a value selected between 1 and 20;
reacting G-Y1mY2k with the hydrophobic layer to obtain a graphene self-assembled precursor layer comprising a hydrophobic layer covalently linked to the dielectric layer and covered by a graphene precursor layer; and
transforming the deposited first graphene molecular precursor into a surface bound graphene interfacial layer.

69. The method according claim 68, wherein D is an aromatic hydrocarbon (PAH) optionally comprising heteroatoms selected from silicon, sulfur, nitrogen and oxygen.

70. The method of claim 68, wherein X² is selected from the group consisting of C₁₋₈ siloxyl, sulfonyl, phosphonate, —SiR¹R²R³, —NR⁴R⁵, —R⁵COOR⁶R⁷SH wherein R¹, R², and R³ are independently selected from H, —OH, —Cl, —Br, —F, —I, C₁₋₈ saturated or unsaturated optionally derivatized alkyl, and at least one of R¹, R², and R³ is —Cl, —Br, —F or —I; R⁴ and R⁵ are independently selected from H, C₁₋₈ saturated or unsaturated optionally derivatized alkyl; R⁶ is H or C₁₋₈ saturated or unsaturated optionally derivatized alkyl; R⁷ is a bond or C₁₋₈ saturated or unsaturated optionally derivatized alkyl.

71. The method of claim 68, wherein the basic functional group is selected from the group consisting of —NR⁴R⁵ wherein R⁴ and R⁵ are independently selected from —H, C₁₋₈ saturated or unsaturated alkyl, and A is selected from —R⁶COOH, —R⁷SO₂, —R⁸PO₃H₂, wherein R⁶, R⁷ and R⁸ are independently a C₁₋₈ saturated or unsaturated optionally derivatized alkyl.

72. The method of claim 68, wherein G-Y² is selected from: rubrene, perylene tetra carboxylic acid (PTAS), perylenetetracarboxylic dianhydride (PTCDA), copper metallocene, coronene, hexabenzocoronene, hexaphenyl benzene and halogenated derivatives thereof.

73. The method of claim 68, further comprising detecting Raman scattering while radiating with IR light, characterizing presence of graphene and arresting the radiation of light when the Raman scattering is indicative of a presence of a full layer of graphene or detecting Rayleigh scattering while radiating with IR light and adjusting the intensity of the IR radiation in order to maintain the temperature at below 400° C.
